(19) United States
(12) Patent Application Publication
(10) Pub. No.: US 2026/0271379 A1
(43) Pub. Date: Sep. 10, 2026

(54) SEMICONDUCTOR DEVICE ISOLATION STRUCTURES UNDER EPITAXIAL FEATURES

(71) Applicant: TAIWAN SEMICONDUCTOR MANUFACTURING COMPANY, LTD., Hsinchu (TW)

(72) Inventors: Chih-Yu LIU, Changhua County (TW); Sung-En LIN, Hsinchu County (TW); Tai-Jung KUO, Hsinchu City (TW); Shu Ling LIAO, Taichung City (TW)

(73) Assignee: TAIWAN SEMICONDUCTOR MANUFACTURING COMPANY, LTD., Hsinchu (TW)

(21) Appl. No.: 19/071,235

(22) Filed: Mar. 5, 2025

(51) Int. Cl. H10D 84/83; H10D 30/00; H10D 30/01; H10D 30/43; H10D 62/10; H10D 62/13; H10D 62/60; H10D 64/66

(52) U.S. Cl. CPC H10D 84/8312; H10D 30/014; H10D 30/0191; H10D 30/43; H10D 30/502; H10D 62/102; H10D 62/115; H10D 62/121; H10D 62/151; H10D 62/60; H10D 64/675; H10D 84/832

(57) ABSTRACT

A method includes following steps. First and second gate structures are formed over a first active region and a second active region. First and second source/drain recesses are etched respectively in the first and second active regions. First and second epitaxial layers are in bottom portions of the first and second source/drain recesses, respectively. A protective layer is formed lining the first source/drain recess. A first protective structure is over the protective layer. A second protective structure is formed over the second epitaxial layer. With the first and second protective structures in place, the second source/drain recess is laterally expanded. First and second epitaxial structures are formed in the first and second source/drain recesses, respectively.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2, 3, 4A, 4B, 5, 6A, 18C, and 18D are cross-sectional views of intermediate stages in the manufacturing of GAA-FETs, in accordance with some embodiments, corresponding to reference cross-section A-A′ illustrated in FIG. 1 that extends through a gate region along a longitudinal axis of the gate region.

FIGS. 6B, 7A, 7B, 8A, 8B, 9A, 9B, 10A, 10B, 11A, 11B, 12A, 12B, 13A, 13B, 13C, 14A, 14B, 14C, 15A, 15B, 16A, 16B, 17A, 17B, 18A, 18B, 19A, and 19B are cross-sectional views of intermediate stages in the manufacturing of GAA-FETs, in accordance with some embodiments, corresponding to reference cross-section B-B′ illustrated in FIG. 1 that extends through a fin along a longitudinal axis of the fin.

FIGS. 15C-15D are cross-sectional views of intermediate stages in the manufacturing of GAA-FETs, in accordance with some embodiments, corresponding to reference cross-section C-C′ illustrated in FIG. 1 that extends through source/drain regions along the longitudinal direction of the gate region.

FIGS. 20A, 20B, 21A, 21B, 22A, 22B, 23A, 23B, 24A, 24B, 25A, 25B, 26A, 26B, 27A, 27B, 28A, 28B, 29A, 29B, 30A, 30B, 31A, 31B, 32A, 32B are cross-sectional views of intermediate stages in the manufacturing of GAA-FETs, in accordance with some embodiments, corresponding to reference cross-section B-B′ illustrated in FIG. 1 that extends through a fin along a longitudinal axis of the fin.

FIGS. 28C and 28D illustrate reference cross-section C-C′ illustrated in FIG. 1 that extends through source/drain regions along the longitudinal direction of the gate region.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a nanosheet transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents.

An integrated circuit (IC) structure comprises multiple regions, each containing transistors that may serve for distinct functions. These transistors may vary in size depending on their specific operational requirements. For example, transistors demanding higher on-current levels are fabricated with larger source/drain epitaxial regions compared to those with more relaxed on-current specifications. To create transistors with enlarged source/drain epitaxial regions, an additional lateral etching process is performed to the source/drain recesses of these high-current demand transistors. This process expands the recesses laterally while leaving the source/drain recesses of transistors with lower on-current requirements unchanged, for example, by masking the source/drain recesses of the transistors with lower on-current requirements using a patterned mask. However, the lateral etching step may unintentionally etch the underlying un-doped epitaxial layers within the source/drain recesses. This unintended etching results in a height difference between the un-doped epitaxial layers of transistors with high on-current demands and those with more relaxed on-current requirements. Consequently, this height difference may elevate the risk of leakage currents when isolation layers are subsequently deposited over the un-doped epitaxial layers.

To mitigate this risk, the present disclosure, in various embodiments, provides additional protective structures formed over the un-doped epitaxial layers prior to the lateral etching step. These protective structures prevent the un-doped epitaxial layers from being unintentionally etched during the lateral etching process. By maintaining uniformity in the height of the un-doped epitaxial layers between high-current-demand and lower-current-demand transistors, the risk of leakage currents can be reduced when isolation layers are deposited over these un-doped epitaxial layers.

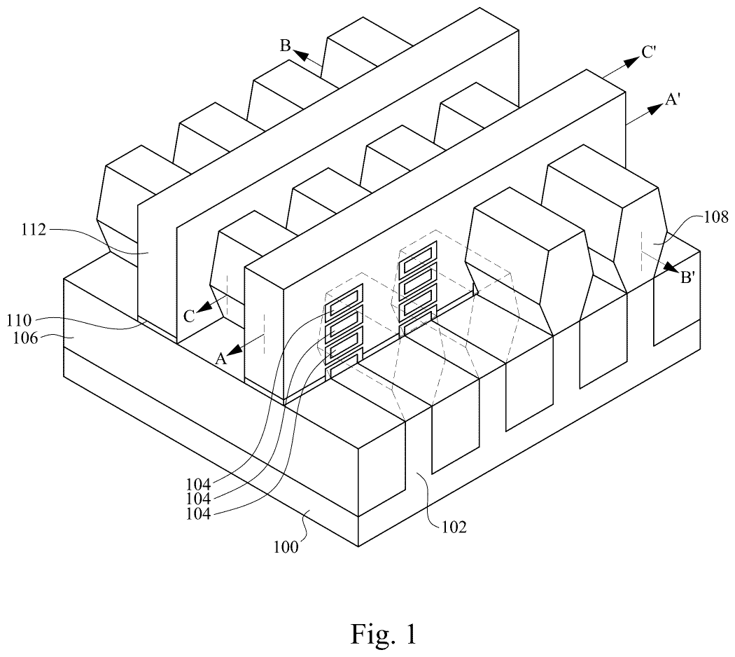

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

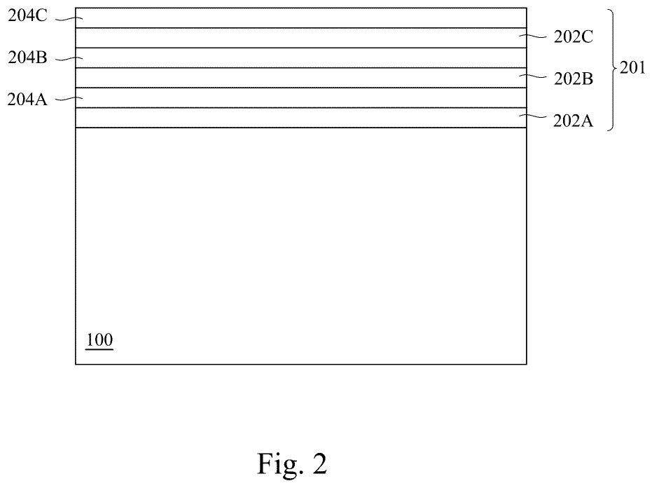

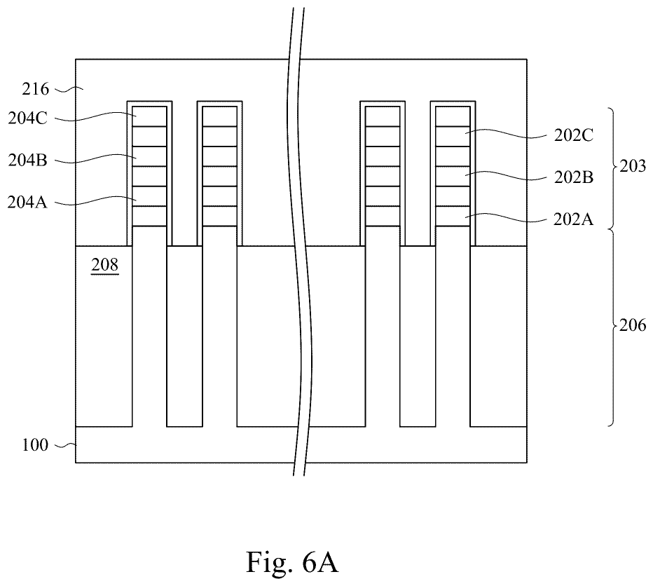

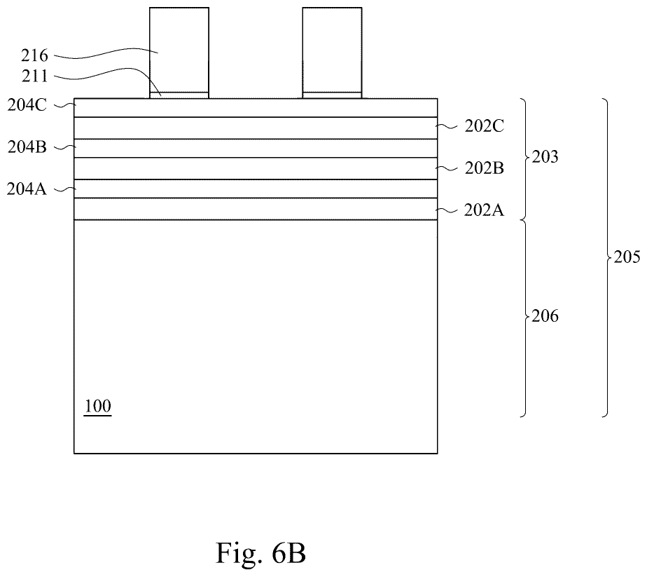

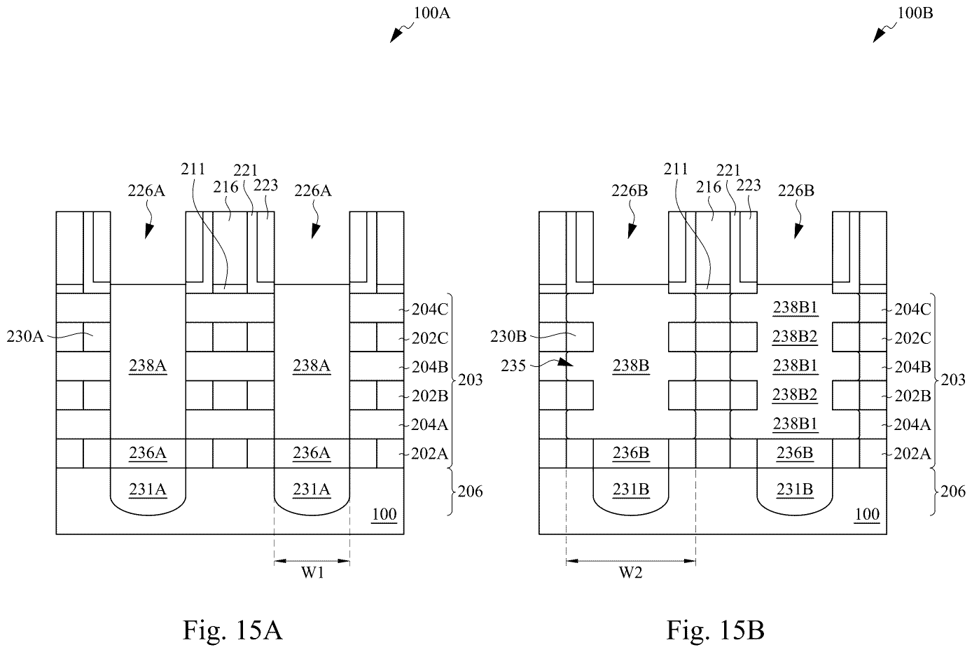

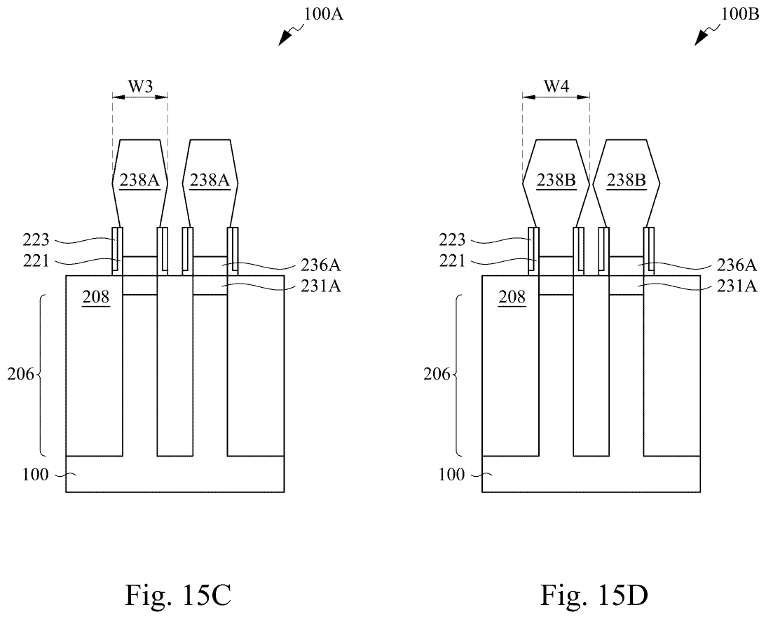

FIGS. 2 through 19B are cross-sectional views of intermediate stages in the manufacturing of GAA-FETs, in accordance with some embodiments. FIGS. 2, 3, 4A, 4B, 5, 6A, 18C, and 18D illustrate reference cross-section A-A′ illustrated in FIG. 1 that extends through a gate region along a longitudinal axis of the gate region. FIGS. 6B, 7A, 7B, 8A, 8B, 9A, 9B, 10A, 10B, 11A, 11B, 12A, 12B, 13A, 13B, 13C, 14A, 14B, 14C, 15A, 15B, 16A, 16B, 17A, 17B, 18A, 18B, 19A, and 19B illustrate reference cross-section B-B′ illustrated in FIG. 1 that extends through a fin along a longitudinal axis of the fin. FIGS. 15C-15D illustrate reference cross-section C-C′ illustrated in FIG. 1 that extends through source/drain regions along the longitudinal direction of the gate region.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

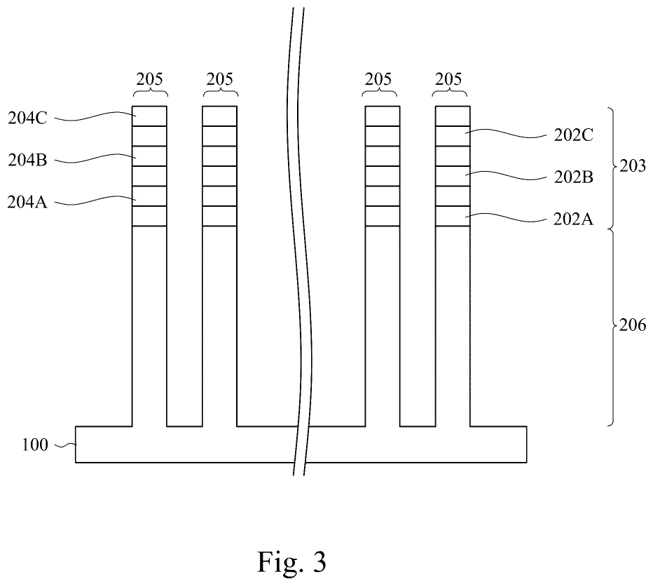

Referring now to FIG. 3, fin structures 206 are formed in the substrate 100 and nanostructures 203 are formed in the multi-layer stack 201, in accordance with some embodiments. Each fin structure 206 and corresponding nanostructures 203 directly above the fin structure 206 can be collectively referred to as an active region 205. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

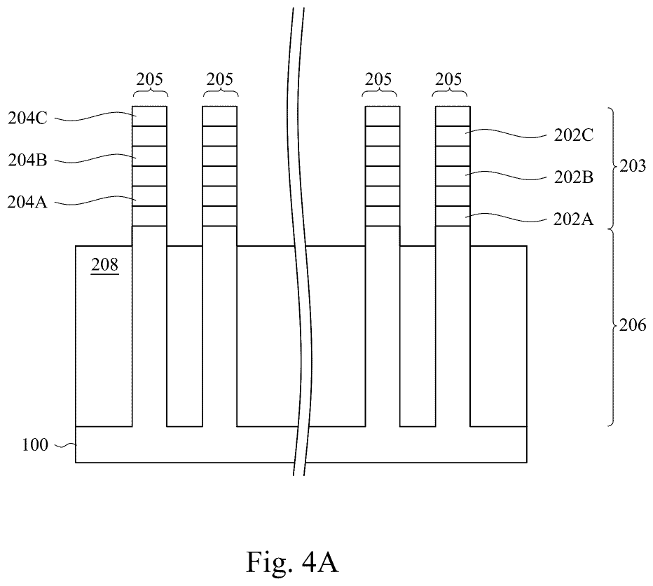

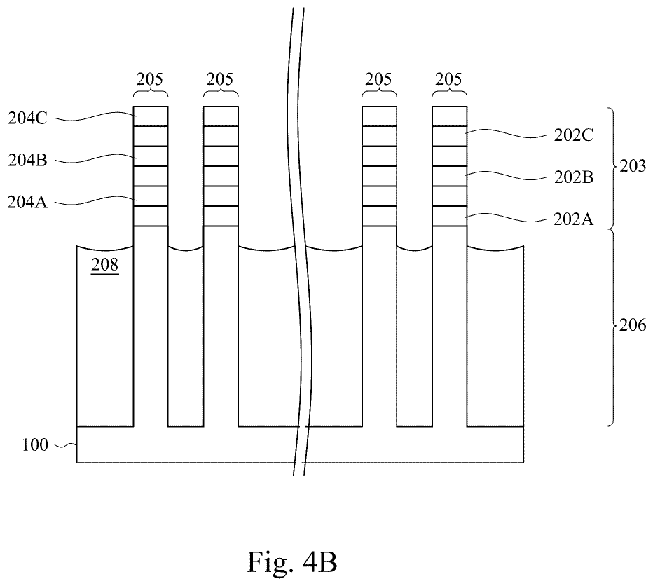

In FIG. 4A, shallow trench isolation (STI) regions (also referred to as isolation features) 208 are formed adjacent the fin structures 206 and alongside the active regions 205. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, or may be non-planar. For example, the top surfaces of the STI regions 208 may be a convex surface, a concave surface (such as dishing, as illustrated in FIG. 4B), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4B is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4A or 4B, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

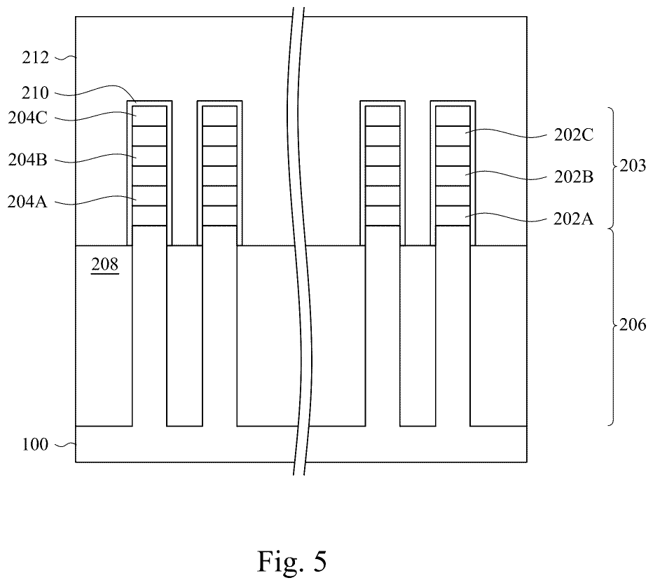

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210. The dummy gate layer 212 may be deposited over the dummy dielectric layer 210 and then planarized, such as by a CMP. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

In FIGS. 6A and 6B, the dummy gate layer 212 and the dummy dielectric layer 210 are patterned to form dummy gates 216 and dummy gate dielectrics 211, respectively, by using suitable photolithography and etching techniques. The dummy gates 216 cover respective channel regions of the fin structures 206. The dummy gates 216 may also have a lengthwise direction substantially perpendicular to the lengthwise direction of respective fin structures 206.

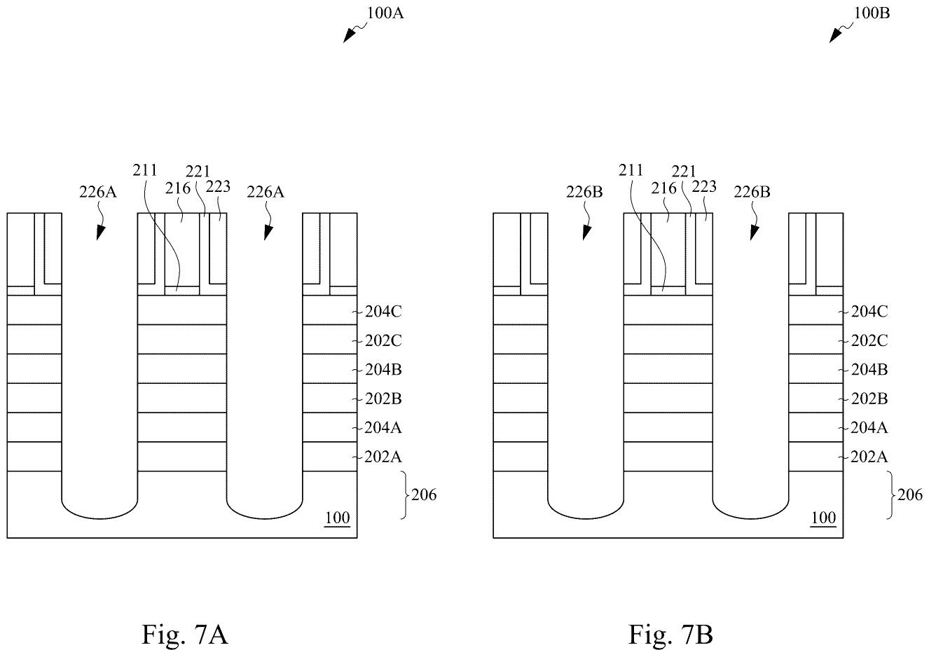

FIGS. 7A and 7B illustrate two example device regions 100A and 100B within the substrate 100, after forming source/drain recesses 226 in the nanostructures 203 and the fin structures 206 in these device regions 100A and 100B. Throughout the description, the device region 100A is a region in the substrate 100 in which transistors with smaller source/drain epitaxial features are formed, and the device region 100B is a region in the substrate 100 in which transistors with larger source/drain epitaxial features are formed.

In FIGS. 7A and 7B, prior to forming the source/drain recesses 226, first gate spacers 221 are formed at opposite sidewalls of each dummy gate 216, and second gate spacers 223 are formed over the first gate spacers 221. The gate spacers 221 and 223 are formed by, for example, depositing a first spacer layer on top surfaces of the STI regions 208, top surfaces and sidewalls of the fin structures 206, the nanostructures 203 and sidewalls of the dummy gates 216 and the dummy gate dielectric 211, depositing a second spacer layer on the first spacer layer, followed by patterning the first and second spacer layers into the first and second gate spacers 221 and 223 by using one or more suitable etching techniques, e.g., an anisotropic etching process. In some embodiments, the first gate spacers 221 may be formed of silicon oxide, silicon nitride, silicon oxynitride, or the like, using techniques such as thermal oxidation or deposited by CVD, ALD, or the like. The second gate spacers 223 may be formed of a material having a different etch rate than the material of the first gate spacers 221, such as silicon oxide, silicon nitride, silicon oxynitride, or the like, and may be deposited by CVD, ALD, or the like.

As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer and the second spacer layer may be etched using a suitable etching process, such as an isotropic etching process (e.g., a wet etching process), an anisotropic etching process (e.g., a dry etching process), or the like. In some embodiments, the material of the second spacer layer has a different etch rate than the material of the first spacer layer, such that the first spacer layer may act as an etch stop layer when patterning the second spacer layer and such that the second spacer layer may act as a mask when patterning the first spacer layer. For example, the second spacer layer may be etched using an anisotropic etch process wherein the first spacer layer acts as an etch stop layer, wherein remaining portions of the second spacer layer form second spacers 223. Thereafter, the second spacers 223 acts as a mask while etching exposed portions of the first spacer layer, thereby forming first spacers 221.

In some embodiments, the first spacers 221 on gate sidewalls are formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the material of second spacers 223), additional spacers may be formed and removed, and/or the like.

Once the first and second gate spacers 221 and 223 have been formed, source/drain recesses 226A are formed in the fin structures 206, the nanostructures 203, and the substrate 100 within the first device region 100A, and source/drain recesses 226B formed in the fin structures 206, the nanostructures 203, and the substrate 100 within the first device region 100A, in accordance with some embodiments. Epitaxial source/drain regions will be subsequently formed in the source/drain recesses 226A within the device region 100A and in the source/drain recesses 226B within the device region 100B. The source/drain recesses 226A and 226 may extend through the first nanostructures 202 and the second nanostructures 204, and into the substrate 100. In some embodiments, as illustrated in 7A and 7B, bottom surfaces of the source/drain recesses 226A and 226B may be lower than bottom surfaces of bottommost first semiconductor layers 202A. This configuration allows for the subsequent formation of un-doped epitaxial layers in the bottom portions of the source/drain recesses 226A and 226B without excessively filling these recesses.

In some embodiments, the source/drain recesses 226A and 226B may be formed by etching the fin structures 206, the nanostructures 203, and the substrate 100 using anisotropic etching processes, such as RIE, NBE, or the like. The first spacers 221 and the second spacers 223 mask portions of the fin structures 206, the nanostructures 203, and the substrate 100 during the etching processes used to form the source/drain recesses 226A and 226B. A single etch process or multiple etch processes may be used to etch each layer of the nanostructures 203 and/or the fin structures 206. Timed etch processes may be used to stop the etching of the source/drain recesses 226A and 226B after the source/drain recesses 226A and 226B reach a target depth.

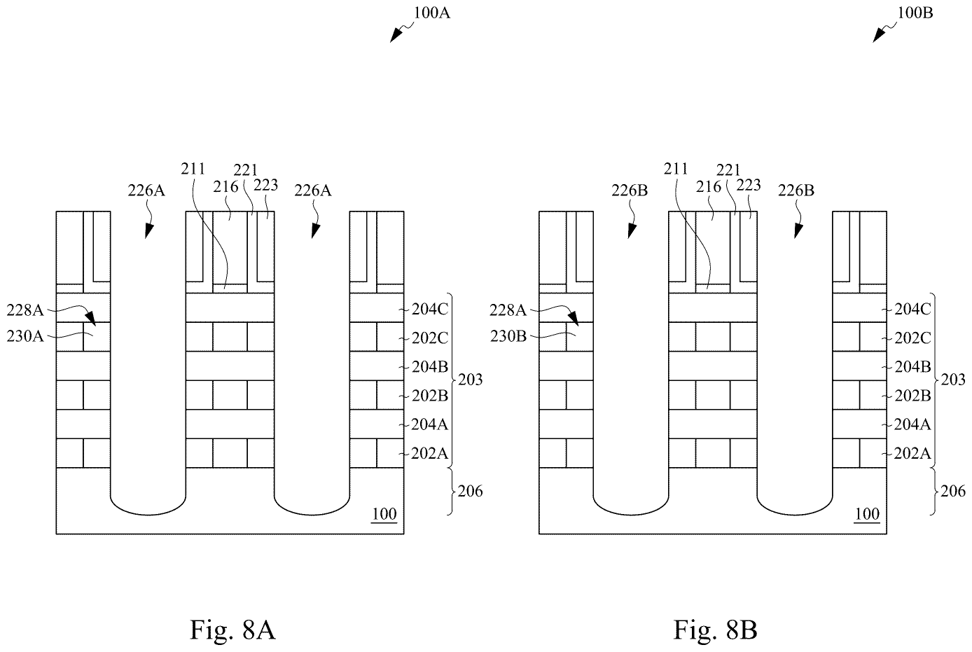

In FIGS. 8A and 8B, portions of sidewalls of the nanostructures 203 formed of the first semiconductor materials (e.g., the first nanostructures 202) exposed by the source/drain recesses 226A, 226B are etched to form sidewall recesses 228A, 228B between corresponding second nanostructures 204 within the device regions 100A and 100B. Although sidewalls of the first nanostructures 202 in recesses 228A, 228B are illustrated as being straight in FIGS. 8A and 8B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

Next, inner spacers 230A and 230B are formed in the sidewall recesses 228A and 228B, respectively. The inner spacers 230A and 230B may be formed by depositing an inner spacer layer (not separately illustrated) overfilling the sidewall recesses 228A within the device region 100A and the sidewall recesses 228B within the device region 100B, followed by removing excessive portions of the inner spacer layer outside the sidewall recesses 228A and 228B by using a suitable etching technique. The inner spacers 230A and 230B act as isolation features between subsequently formed source/drain regions and gate structure. As will be discussed in greater detail below, source/drain regions will be formed in the source/drain recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230A left in the device region 100A and the inner spacers 230B left in the device region 100B. Although outer sidewalls of the inner spacers 230A and 230B are illustrated as being flush with sidewalls of the second nanostructures 204, the outer sidewalls of the inner spacers 230A and 230B may extend beyond or be recessed from sidewalls of the second nanostructures 204.

Moreover, although the outer sidewalls of the inner spacers 230A and 230B are illustrated as being straight in FIGS. 8A and 8B, the outer sidewalls of the inner spacers 230A and 230B may be concave or convex. The inner spacer layer may be etched by an anisotropic etching process, such as RIE, NBE, or the like. The inner spacers 230A and 230B may be used to prevent damage to subsequently formed epitaxial source/drain features by a subsequent etching processes, such as etching processes used to form gate structures.

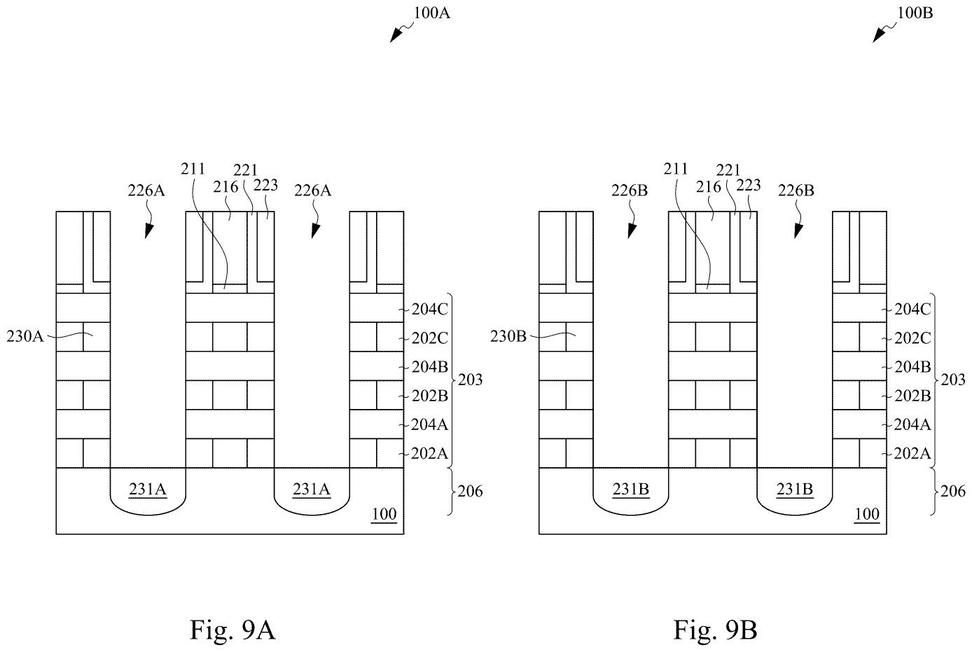

In FIGS. 9A and 9B, first epitaxial layers 231A are formed in bottom portions of the source/drain recesses 226A within the first device region 100A, and first epitaxial layers 231B are formed in bottom portions of the source/drain recesses 226B within the first device region 100A. In some embodiments, first epitaxial layer 231A and 231B can be epitaxially grown on fin structures 206 over substrate 100 with a bottom-up growth method. For example, the first epitaxial layers 231A and 231B may be formed using selective epitaxial growth (SEG), which involves adjusting the growth conditions such that silicon can selectively nucleates and grows on specific crystallographic planes or surfaces. By optimizing parameters such as temperature, pressure, and precursor concentration, growth can be directed to occur primarily at the bottom of the source/drain recesses 226A and 226B. In some embodiments, first epitaxial layers 231A and 231B can include intrinsic silicon without a dopant.

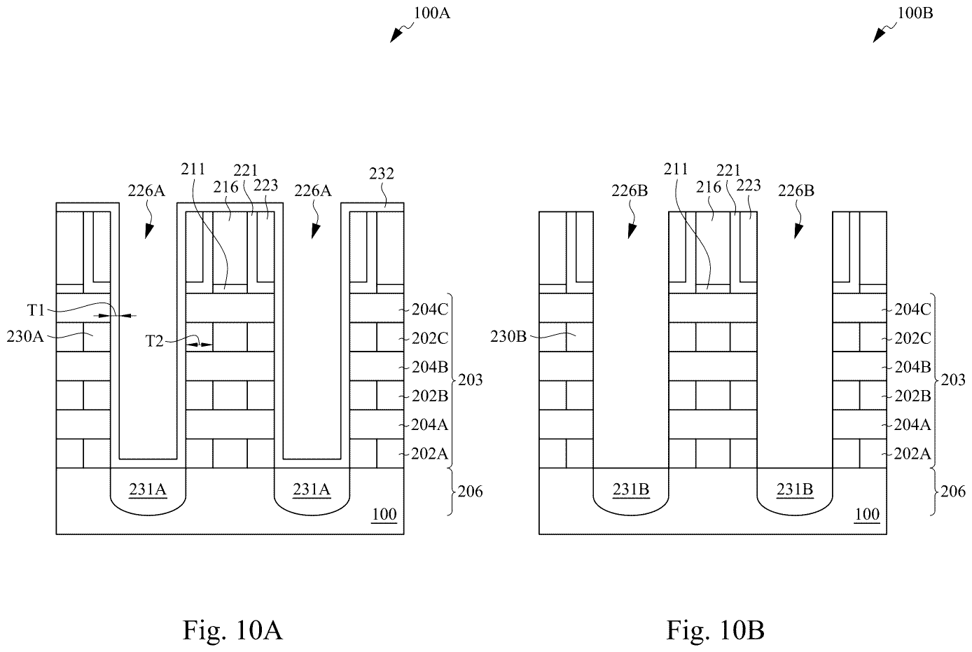

In FIGS. 10A and 10B, a protective layer 232 is formed over the device region 100A, but not over the device region 100B. In some embodiments, the protective layer 232 can be formed by, for example, depositing a blanket layer of protective material globally over the substrate 100 by using ALD or CVD, followed by patterning the blanket layer of protective material into the protective layer 232 by using suitable lithography and etching techniques. In some embodiments, the protective layer 232 is formed of a material different from a material of the inner spacers 230A, 230B and a material of the second nanostructures 204. The material difference allows for the protective layer 232 serving to protect the second nanostructures 204 and the inner spacers 230A within the first device region 100A against a subsequent etching process performed to laterally enlarge the source/drain recesses 226B within the second device region 100B. For example, the protective layer 232 may include a metal oxide such as aluminum oxide or other suitable metal oxides. In some embodiments, the protective layer 232 has a thickness T1, which is less than a thickness T2 of the inner spacers 230A and 230B.

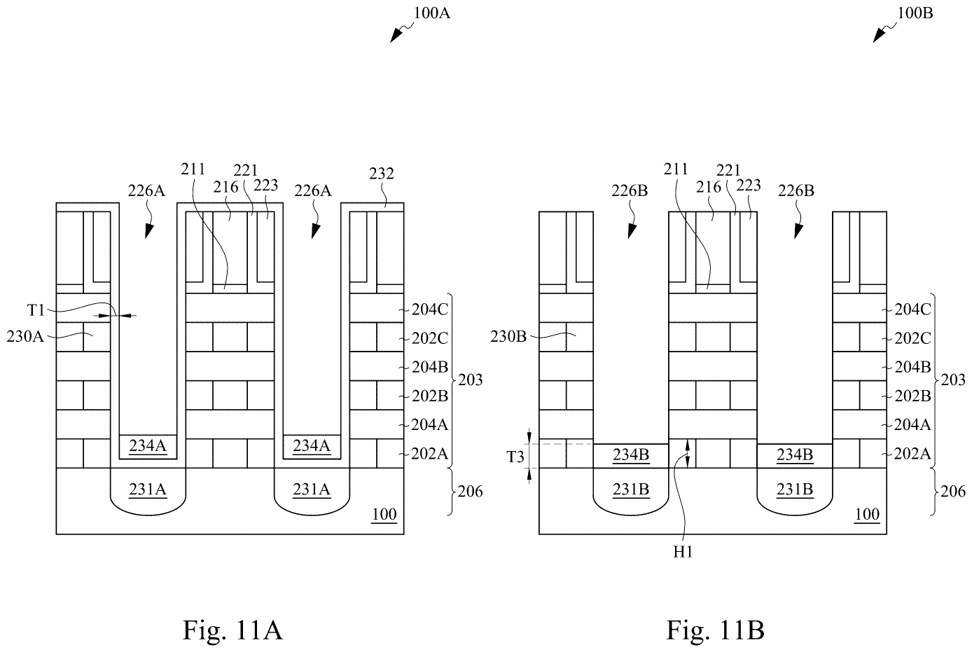

In FIGS. 11A and 11B, protective structures 234A and 234B are formed in the source/drain recesses 226A within the device region 100A and in the source/drain recesses 226B within the device region 100B, respectively. In some embodiments, the protective structures 234A and 234B are formed of a material different from a material of the first epitaxial layers 231A and 231B (e.g., un-doped silicon) and a material of the second nanostructures 204. The choice of a different material for the protective structures 234A and 234B is beneficial, as it provides enhanced etch resistance during subsequent lateral etching processes aimed at expanding the source/drain recesses 226B. This material differentiation allows that the protective structures 234B effectively shield the underlying first epitaxial layers 231B from being etched, recessed, or otherwise consumed during the lateral etching process. Consequently, the uniformity in the heights of first epitaxial layers 231A, 231B can be maintained. In some embodiments, the protective structures 234A and 234B are formed of amorphous carbon (a-C), although other suitable materials different from un-doped silicon can be employed as well.

In some embodiments, the protective structures 234A and 234B are formed in the respective source/drain recesses 226A and 226B in a bottom-up method. For example, the protective structures 234A and 234B are amorphous carbon deposited by a plasma-enhanced CVD (PECVD) process by using a gas mixture comprising a carbon-containing precursor gas (e.g., C₂H₂ or C₃H₆) and a carrier gas (e.g., H₂, Ar and/or He), at a temperature in a range from about 350° C. to about 500° C., and at a pressure in a ragne from about 1 torr to about 10 torr. By depositing the protective structures 234A and 234B under the foregoing selected process conditions, the protective structures 234A and 234B can be formed in bottom-up manner, allowing them to be localized to bottom portions of the source/drain recesses 226A and 226B. Stated differently, if the pressure is excessively low (such as lower than 1 torr) or excessively high (e.g., higher than 10 torr), the amorphous carbon may be deposited as a conformal layer spanning across the entire substrate 100, not deposited as separate protective structures localized to bottom portions of the source/drain recesses 226A and 226B. Similarly, if the temperature is excessively low (such as lower than 350° C.) or excessively high (e.g., higher than 500° C.), the amorphous carbon may be deposited as a conformal layer spanning across the entire substrate 100, not deposited as separate protective structures localized to bottom portions of the source/drain recesses 226A and 226B.

In some embodiments, the protective structures 234A and 234B are deposited to have a thickness that is sufficient to endure the subsequent lateral etching step aimed at expanding the source/drain recesses 226B. In some embodiments, the thickness T3 of the protective structures 234A and 234B is less than a height of the inner spacers 230A and 230B. In this configuration, the protective structures 234B may have a top surface lower than a top surface of a bottommost one of the inner spacers 230B. In some embodiments, a combination of the thickness T1 of the protective layer 232 and the thickness T3 of the protective structure 234A is greater than a height H1 of the inner spacer 230A. In this configuration, the protective structure 234A may have a top surface higher than a top surface of a bottommost one of the inner spacers 230A.

In some embodiments, the top surface of the protective structure 234A is higher than the top surface of the protective structure 234B, and a height difference between the top surface of the protective structure 234A and the top surface of the protective structure 234B is substantially equal to the thickness T1 of the protective layer 232. This height difference between the top surfaces of the protective structures 234A and 234B is due to the presence of the protective layer 232 lining the bottoms of the source/drain recesses 226A, whereas the source/drain recesses 226B do not include this protective layer. In some embodiments, the bottom surface of the protective structure 234A is higher than the bottom surface of the protective structure 234B, and a height difference between the bottom surface of the protective structure 234A and the bottom surface of the protective structure 234B is substantially equal to the thickness T1 of the protective layer 232. This height difference between the bottom surfaces of the protective structures 234A and 234B is due to the presence of the protective layer 232 lining the bottoms of the source/drain recesses 226A, whereas the source/drain recesses 226B do not include this protective layer. In some embodiments, the protective structure 234B has a width greater than a width of the protective structure 234A, with a width difference between the protective structures 234A and 234B being approximately equal to twice the thickness T1 of the protective layer 232. This width difference between the protective structures 234A and 234B is attributed to the presence of the protective layer 232 lining the sidewalls of the source/drain recesses 226A, whereas the source/drain recesses 226B do not include this protective layer.

In some embodiments, within the device region 100B, carbon atoms may diffuse from the protective structures 234A and 234B into the bottommost ones of inner spacers 230B and the underlying first epitaxial layers 231B, because the protective structures 234A and 234B are in contact with the bottommost ones of inner spacers 230B and the underlying first epitaxial layers 231B. On the other hand, within the device region 100A, the protective layer 232 can block the carbon diffusion from the protective structures 234A into the bottommost ones of inner spacers 230A and the underlying first epitaxial layers 231A. Therefore, the first epitaxial layers 231B within the device region 100B may have a greater carbon atomic concentration than the first epitaxial layers 231A within the device region 100A. For example, the first epitaxial layers 231B within the device region 100B may be carbon-doped silicon, and the first epitaxial layers 231A within the device region 100A may remain un-doped silicon. Moreover, the inner spacers 230B within the device region 100B may have a greater carbon atomic concentration than the inner spacers 230A within the device region 100A. For example, the inner spacers 230B within the device region 100B may be carbon-doped, and the inner spacers 230A within the device region 100A may remain un-doped.

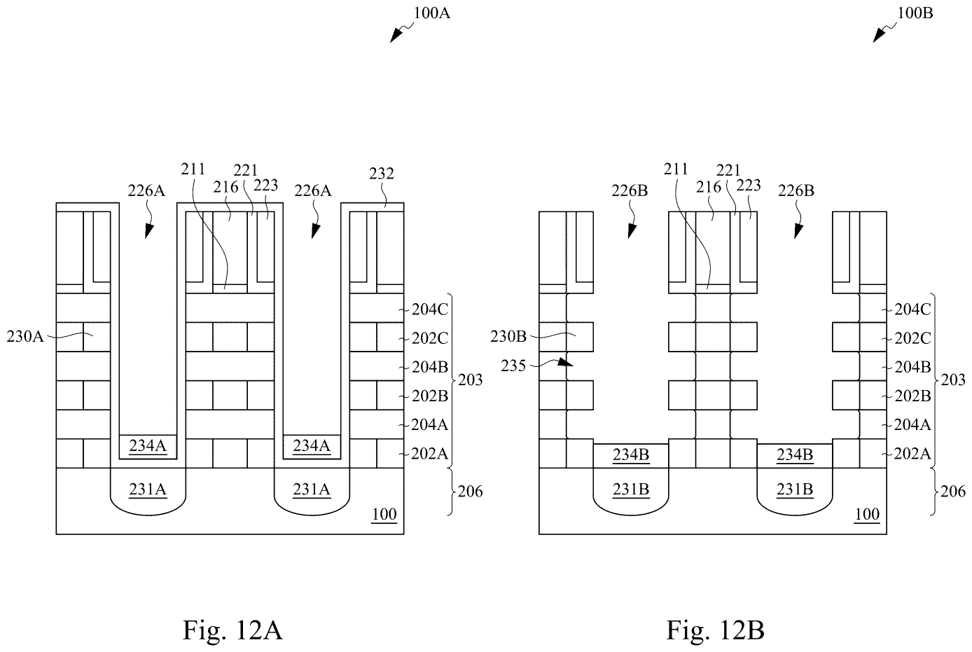

In FIGS. 12A and 12B, a selective etching process is performed to selectively etch the second nanostructures 204 exposed in the source/drain recesses 226B within the device region 100B, while cause no or negligible etching amount in the protective structures 234A, 234B and in the protective layer 232. The selective etching process laterally etches the second nanostructures 204 exposed in the source/drain recesses 226B within the device region 100B, which in turn laterally expands the source/drain recesses 226B to have a larger lateral size. On the other hand, the source/drain recesses 226A within the device region 100A are not expanded by this selective etching process, because all sidewalls of the second nanostructures 204 within the source/drain recesses 226A are covered and protected by the protective layer 232. In some embodiments where the second nanostructures 204 are silicon, the protective layer 232 is aluminum oxide, and the protective structures 234A, 234B are amorphous carbon, the second nanostructures 204 can be selectively etched using, by way of example and not limitation, a mixture of H₂ and NF₃. This plasma mixture acts as an etchant to selectively etch the silicon sidewalls of the second nanostructures 204 with nitric acid, thereby facilitating the lateral expansion of the source/drain recesses 226B within the device region 100B. The etching conditions, such as etchant concentration, temperature, and etching duration, can be controlled to facilitate that the etching is confined to the exposed silicon surfaces of the second nanostructures 204 without compromising the integrity of the protective layer 232, and the protective structures 234A, 234B. For instance, maintaining the etchant at a higher temperature can enhance the selectivity by reducing the etching rate of aluminum oxide and amorphous carbon, which are inherently resistant to the chosen etchant.

In some embodiments, as illustrated in FIG. 12B, the selective etching process results in sidewall recesses 235 at sidewalls of the second nanostructures 204. In the depicted embodiments, upon completion of the selective etching process, sidewalls of the second nanostructures 204 within the device region 100B is non-linear (e.g., concave) and is laterally offset from from interfaces between the first nanostructures 202 and inner spacers 230B. In some other embodiments, the sidewalls of the second nanostructures 204 within the device region 100B may be linear and aligned with interfaces between the first nanostructures 202 and inner spacers 230B.

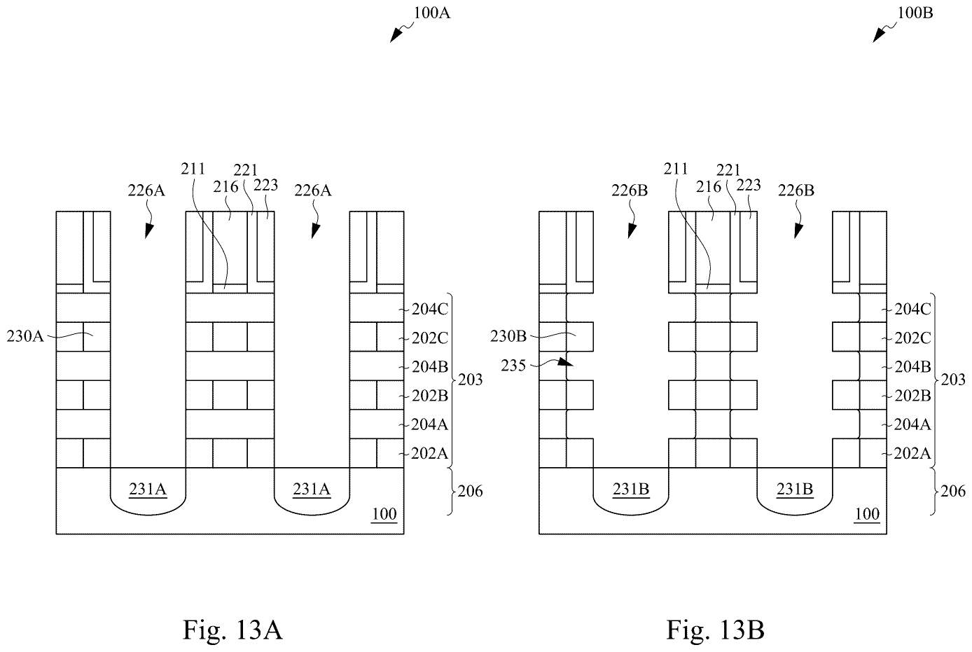

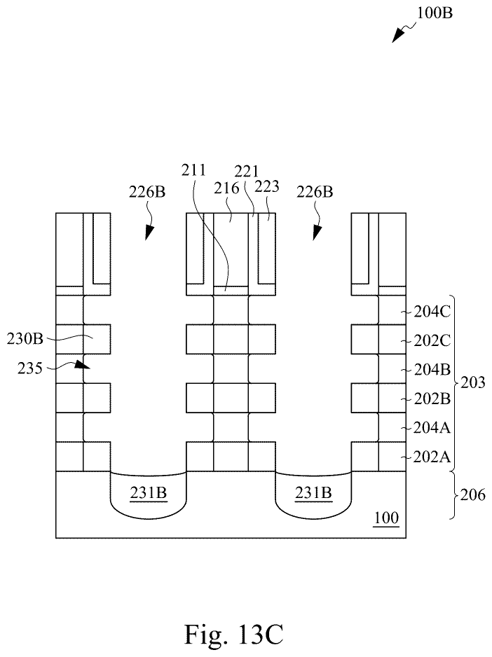

Next, the protective structures 234A, 234B, and the protective layer 232 are removed, and the resultant structure is illustrated in FIGS. 13A and 13B. In some embodiments, the protective structures 234A, 234B, and the protective layer 232 together using a single wet etching process. In some embodiments, the etchant for removing the protective structures 234A, 234B, and the protective layer 232 may include, for example, a mixture of sulfuric acid (H₂SO₄) and hydrogen peroxide (H₂O₂) (also referred to as sulfuric peroxide mixture (SPM)). In some embodiments, the etchant is selective to etch the protective structures 234A, 234B, and the protective layer 232, while cause no or negligible etch amount to the material of the inner spacers 230A, 230B, the material of the second nanostructures 204, and the material of the first epitaxial layers 231A, 231B. Therefore, the inner spacers 230A, 230B, and the second nanostructures 204, and the first epitaxial layers 231A, 231B can remain intact during the etching step of removing the protective structures 234A, 234B, and the protective layer 232. As a result, the uniformity in the heights of first epitaxial layers 231A, 231B can be maintained during this etching step. In some embodiments, the etching process used to remove the protective structures 234A and 234B may cause loss in the first epitaxial layers 231B and no loss in the first epitaxial layers 231A. The loss in the first epitaxial layers 231B results in the formation of non-planar surfaces, such as concave surfaces, on the first epitaxial layers 231A and 231B. This outcome is depicted in FIG. 13C.

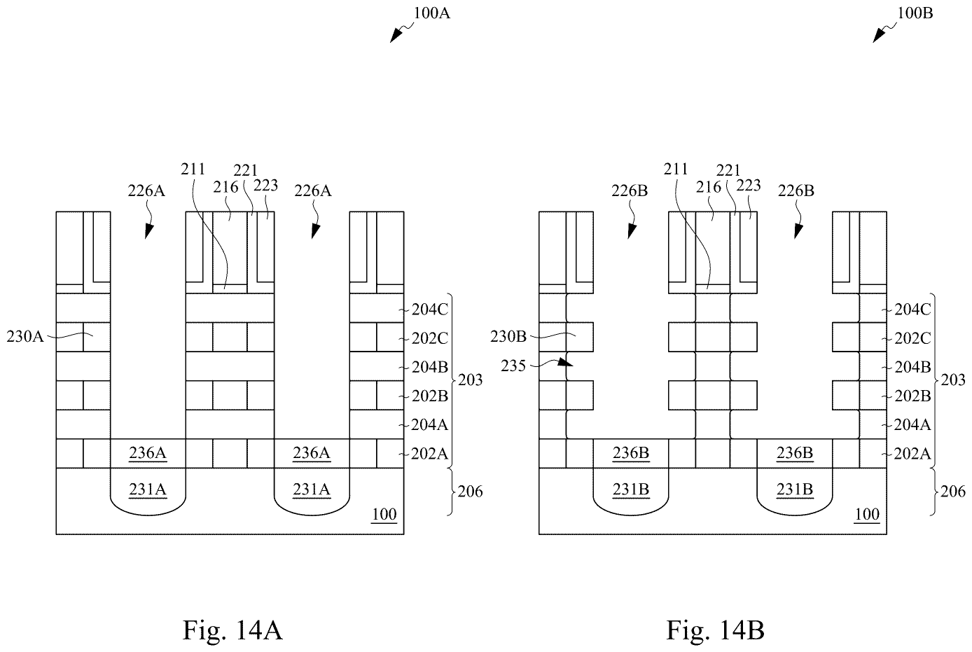

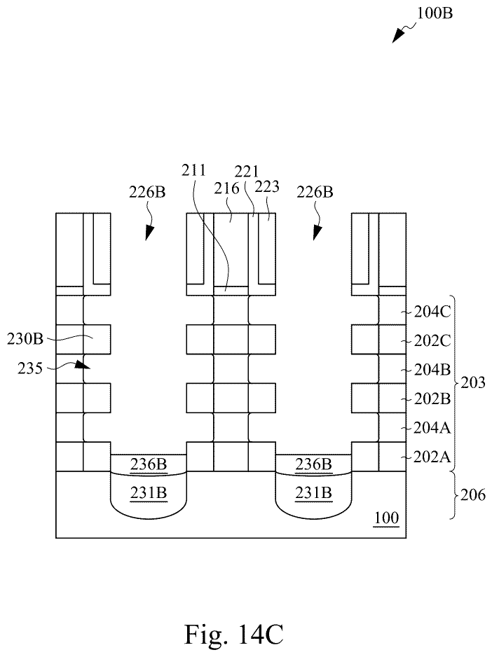

Next, in FIGS. 14A and 14B, bottom isolation structures 236A and 236B are formed in bottom portions of the source/drain recesses 226A within the device region 100A and in the source/drain recesses 226B within the device region 100B, respectively. In some embodiments, the bottom isolation structures 236A and 236B are formed of a material different from a material of the first epitaxial layers 231A and 231B. For example, the bottom isolation structures 236A and 236B are formed of a dielectric material, which has a lower conductivity than the underlying silicon materials of the first epitaxial layers 231A and 231B. In this way, the bottom isolation structures 236A and 236B can serve to prevent leakage currents from the subsequently formed source/drain epitaxial features into the substrate 100. Because the uniformity of heights of first epitaxial layers 231A, 231B can be maintained, the bottom isolation structures 236A and 236B can be formed with top surfaces at substantially the same elevation. For example, in some embodiments, an elevation difference between a top surface of the bottom isolation structure 236A and a top surface of the bottom isolation structure 236B is less than 10%, 5% or even 3% of a thickness of the bottom isolation structure 236A. In some embodiments, the bottom isolation structures 236A is formed of silicon nitride, silicon oxynitride, silicon oxide, or the like, by using a bottom-up growth method. In some embodiments, the bottom isolation structures 236A, 236B have top surfaces substantially level with, lower than or higher than top surfaces of bottommost ones of the inner spacers 230A, 230B. In some embodiments where the protective structure removal step causes loss in the first epitaxial layers 231B, top surfaces of the bottom isolation structures 236B as illustrated in FIG. 14C may be not coplanar with top surfaces of the bottom isolation structures 236A. For example, the top surfaces of the bottom isolation structures may be lower than the with top surfaces of the bottom isolation structures 236A by a vertical distance in a range from about 1 nm to about 3 nm.

In FIGS. 15A-15D, epitaxial source/drain regions (also referred to as epitaxial features or epitaxial source/drain features) 238A, 238B are formed in the source/drain recesses 226A, 226B, respectively. In some embodiments, the source/drain regions 238A may exert stress on the second nanostructures 204 within the device region 100A, thereby improving device performance within the device region 100A. Similarly, the source/drain regions 238B may exert stress on the second nanostructures 204 within the device region 100B, thereby improving device performance within the device region 100B.

In some embodiments, as illustrated in FIG. 15B, the epitaxial source/drain region 238B has a plurality of first epitaxial portions 238B1 and a plurality of second epitaxial portions 238B2 alternating with the first epitaxial portions 238B1, and the second epitaxial portions 238B2 has a maximal width less than a maximal width of the first epitaxial portions 238B1. The first epitaxial portions 238B1 have opposite sidewalls interfacing the second nanostructures 204, and the second epitaxial portions 238B2 have opposite sidewalls interfacing the inner spacers 230B. The width difference between the first epitaxial portions 238B1 and the second epitaxial portions 238B2 results from the etching step aimed at laterally expanding the source/drain recesses 226B, as illustrated in FIGS. 12A-12B. On the other hand, because the source/drain recesses 226A are not expanded by this etching step, the epitaxial source/drain regions 238A have a substantially uniform width when viewed in a cross-sectional view as shown in FIG. 15A. In particular, in FIG. 15A, the epitaxial source/drain regions 238A have substantially linear sidewalls, and in FIG. 15B, the epitaxial source/drain regions 238B have non-linear sidewalls due to the lateral expansion of source/drain recesses 226B. As illustrated in cross-sectional views of FIGS. 15A and 15B, the epitaxial source/drain regions 238B has a maximal width W2 greater than a maximal width W1 of the epitaxial source/drain regions 238A.

In some embodiments, as shown in other cross-sectional views in FIGS. 15C and 15D, a maximal width W3 of the epitaxial source/drain regions 238A is less than a maximal width W4 of the epitaxial source/drain regions 238B. The width difference may be attributed to the enlarged source/drain recesses 223B in which the epitaxial source/drain regions 238B are grown. In some embodiments, the adjacent epitaxial source/drain regions 238A may merge, and/or the adjacent epitaxial source/drain regions 238B may merge. In some embodiments, a portion of the epitaxial source/drain region 238A and a portion of the epitaxial source/drain region 238B overhang the STI region 208.

As illustrated in FIGS. 15A and 15B, the epitaxial source/drain regions 238A are formed in the source/drain recesses 226A such that a dummy gate 216 is disposed between respective neighboring pairs of the epitaxial source/drain regions 238A, and the epitaxial source/drain regions 238B are formed in the source/drain recesses 226B such that a dummy gate 216 is disposed between respective neighboring pairs of the epitaxial source/drain regions 238B. In some embodiments, the gate spacers 221, 223 are used to separate the epitaxial source/drain regions 238A, 238B from the dummy gates 216, and the inner spacers 230A, 230B are used to separate the epitaxial source/drain regions 238A, 238B from the first nanostructures 202 by an appropriate lateral distance so that the epitaxial source/drain regions 238A, 238B do not short out with subsequently formed gates of the resulting GAA-FETs.

In some embodiments, the epitaxial source/drain regions 238A, 238B may include any acceptable material appropriate for n-type GAA-FETs. For example, if the second nanostructures 204 are silicon, the epitaxial source/drain regions 238A, 238B may include materials exerting a tensile strain on the second nanostructures 204, such as silicon carbide, phosphorous doped silicon carbide, silicon phosphide, or the like. In some embodiments, the epitaxial source/drain regions 238A, 238B may include any acceptable material appropriate for p-type GAA-FETs. For example, if the second nanostructures 204 are silicon, the epitaxial source/drain regions 238A, 238B may comprise materials exerting a compressive strain on the second nanostructures 204, such as silicon germanium, boron doped silicon germanium, germanium, germanium tin, or the like. The epitaxial source/drain regions 238A, 238B may have surfaces raised from the topmost nanostructures 204C and may have facets.

The epitaxial source/drain regions 238A, 238B may be implanted with dopants to form source/drain regions, followed by an anneal. The source/drain regions may have an impurity concentration of between about 1×10¹⁸ atoms/cm³ and about 1×10²³ atoms/cm³. The n-type and/or p-type impurities for source/drain regions may be any of the impurities previously discussed. In some embodiments, the epitaxial source/drain regions 238A, 238B may be in situ doped during growth.

As a result of the epitaxy processes used to form the epitaxial source/drain regions 238A, 238B, upper surfaces of the epitaxial source/drain regions 238A, 238B have facets which expand laterally outward beyond sidewalls of the fins 206, as shown in FIGS. 15C and 15D. In the embodiments illustrated in FIGS. 15C and 15D, the spacers 221, 223 may be left on a top surface of the STI regions 208 thereby blocking the lateral epitaxial growth. In some other embodiments, the spacer etch used to form the first spacers 221, 223 may be adjusted to remove the spacer material to allow the epitaxially grown region to extend to the surface of the STI region 208.

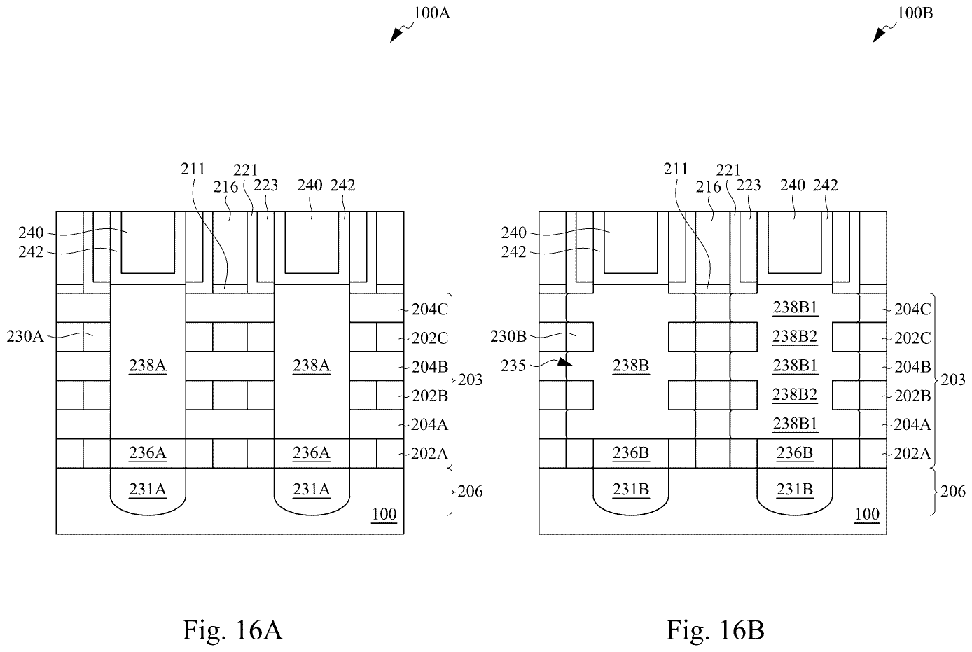

In FIGS. 16A and 16B, an interlayer dielectric (ILD) layer 240 is formed over the structure illustrated in FIGS. 15A-15D. The ILD layer 240 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 242 is formed between the ILD layer 240 and the epitaxial source/drain regions 238A, 238B. The CESL 242 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 240.

After the CESL 242 and the ILD layer 240 over the epitaxial source/drain regions 238A, 238B, a planarization process, such as a CMP, may be performed to level the top surface of the ILD layer 240 with the top surfaces of the dummy gates 216. After the planarization process, top surfaces of the dummy gates 216, the gate spacers 221, 223, and the ILD layer 240 are level within process variations. Accordingly, the top surfaces of the dummy gates 216 are exposed through the ILD layer 240.

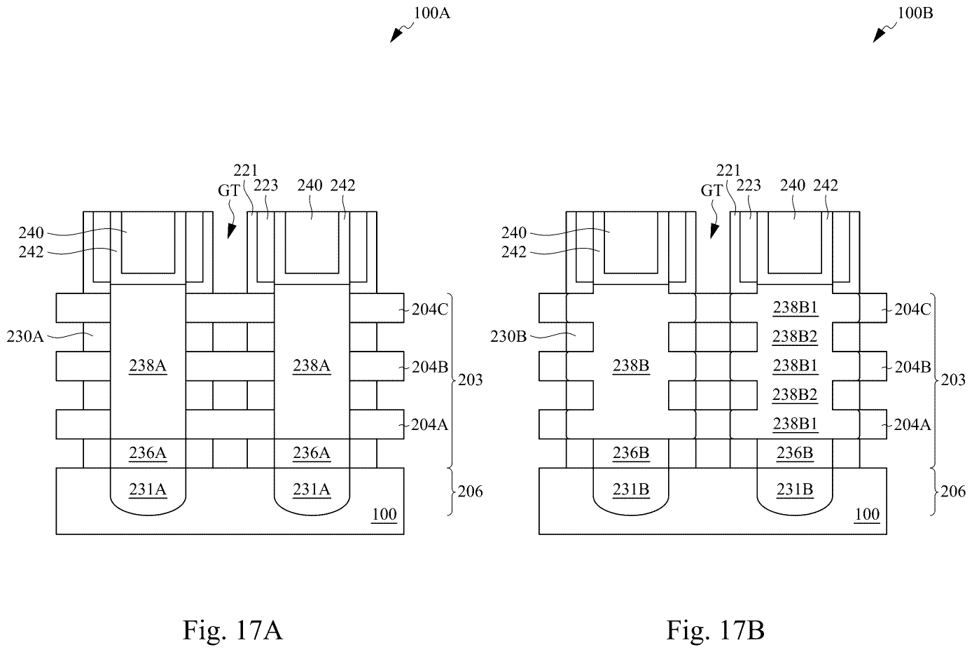

In FIGS. 17A and 17B, the dummy gates 216 are removed in one or more etching steps, so that gate trenches GT are formed between corresponding gate spacers 221. In some embodiments, portions of the dummy gate dielectrics 211 in the gate trenches GT are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than ILD layer 240 and the gate spacers 221, 223. Each gate trench GT exposes and/or overlies portions of nanostructures 204, which will serve as channel regions in subsequently completed GAA-FETs. The nanostructures 204 serving as the channel regions are disposed between neighboring pairs of the epitaxial source/drain regions 238A, 238B. During the removal, the dummy dielectric layers 211 may be used as etch stop layers when the dummy gates 216 are etched. The dummy dielectric layers 211 may then be removed after the removal of the dummy gates 216.

After the dummy gates 216 are removed, the first nanostructures 202 in the gate trenches GT are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires. In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202.

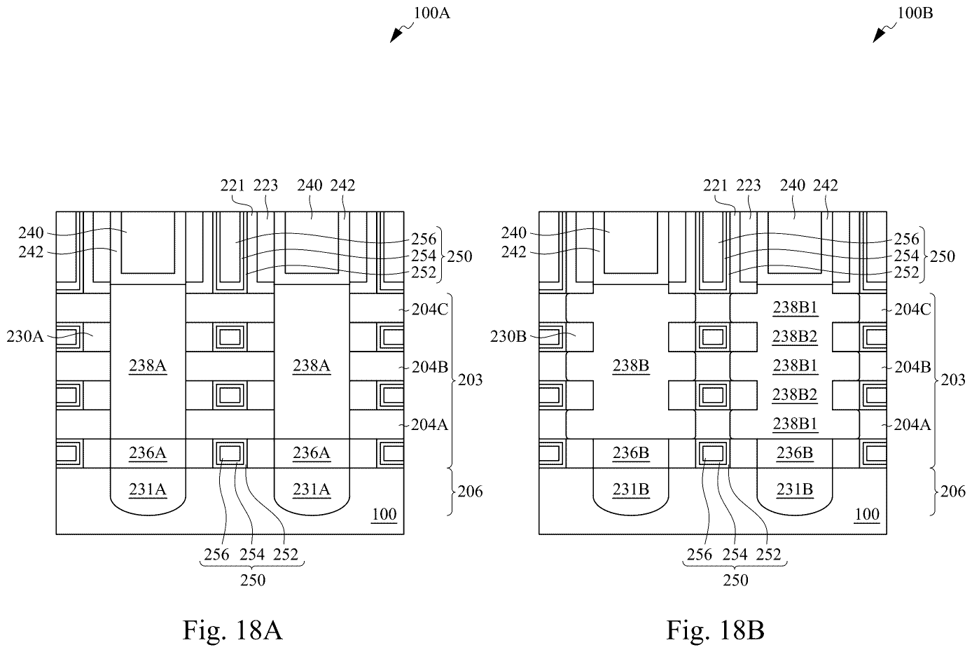

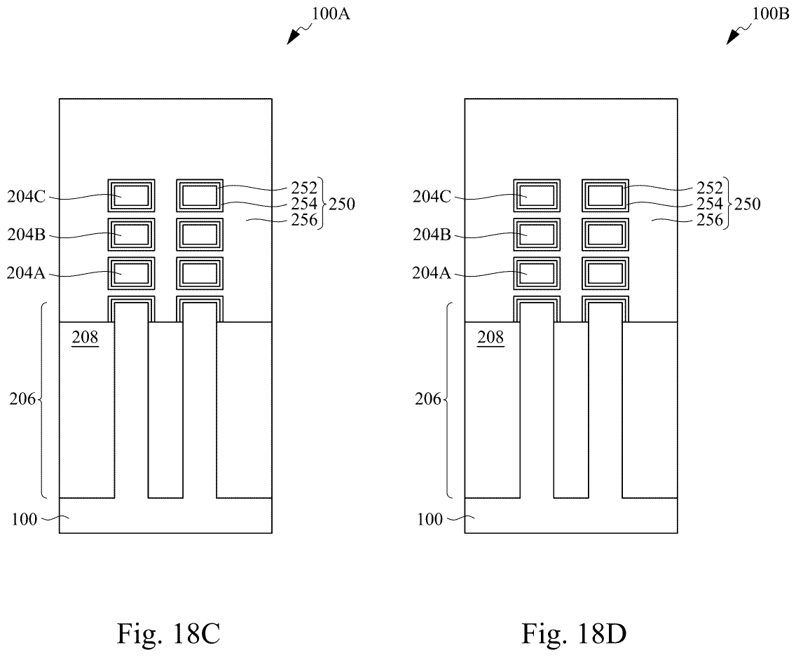

In FIGS. 18A-18D, replacement gate structures 250 are respectively formed in the gate trenches GT to surround each of the nanostructures 204 suspended in the gate trenches GT. The gate structures 250 formed within the device region 100A may be final gates of GAA FETs within the device region 100A, and the gate structures 250 formed within the device region 100B may be final gates of GAA FETs within the device region 100B. The final gate structure may be a high-k/metal gate stack, however other compositions are possible. In some embodiments, one of the gate structures 250 forms the gate associated with the multi-channels provided by the plurality of nanostructures 204. For example, high-k/metal gate structures 250 are formed within the sheet-to-sheet spaces provided by the release of nanostructures 204. In various embodiments, the high-k/metal gate structure 250 includes a gate dielectric layer 252 formed around the nanostructures 204, a work function metal layer 254 formed around the gate dielectric layer 252, and a fill metal layer 256 formed around the work function metal layer 254 and filling a remainder of gate trenches GT. Formation of the high-k/metal gate structures 250 may include one or more deposition processes to form various gate materials, followed by a CMP processes to remove excessive gate materials, resulting in the high-k/metal gate structures 250 having top surfaces level with a top surface of the ILD layer 240. As illustrated in the cross-sectional view of FIG. 18C, the high-k/metal gate structure 250 surrounds each of the nanostructures 204 within the device region 100A, and thus is referred to as a gate of a GAA FET within the device region 100A. As illustrated in the cross-sectional view of FIG. 18D, the high-k/metal gate structure 250 surrounds each of the nanostructures 204 within the device region 100B, and thus is referred to as a gate of a GAA FET within the device region 100B.

In some embodiments, the gate dielectric layer 252 includes an interfacial layer interfacing the nanostructures 204 and the fin structures 206, and a high-k dielectric layer formed over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the nanostructures 204 exposed in the gate trenches GT are oxidized into silicon oxide to form interfacial layer. In some embodiments, the high-k dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the work function metal layer 254 may be a multilayered film which includes a plurality of metal layers. For example, the work function metal layer 254 serves to provide a suitable work function for the high-k/metal gate structures 250. For an n-type GAA FET, the work function metal layer 254 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the work function metal layer 254 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer 256 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

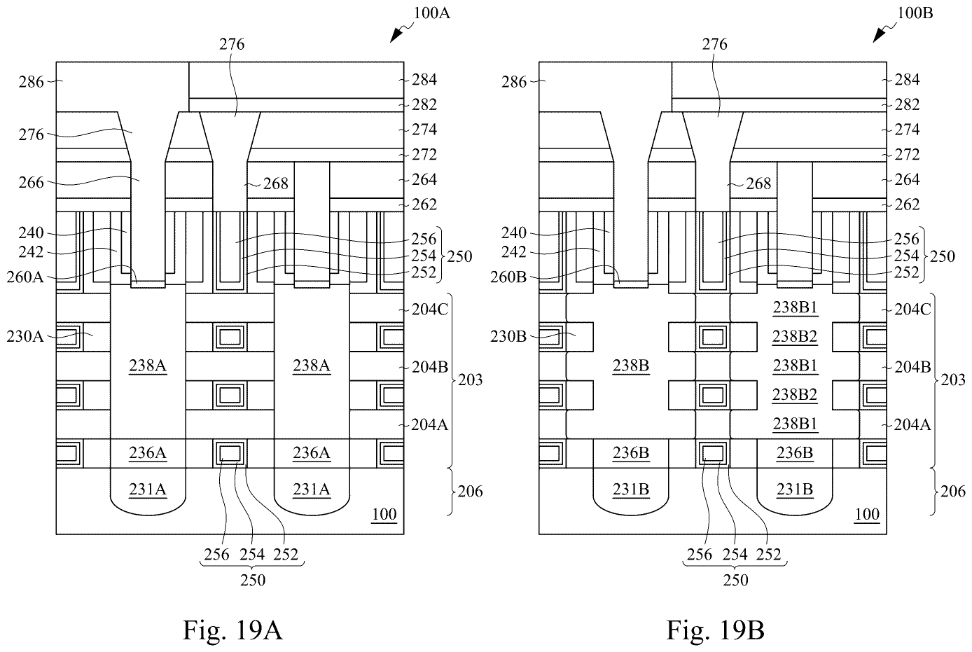

In FIGS. 19A and 19B, contact metals and their surrounding dielectrics are formed in middle-end-of-line (MEOL) processing. For example, an etch stop layer (ESL) 262 is deposited over the structure as shown in FIGS. 18A-18D, followed by depositing an ILD layer 264 over the ESL 262. In some embodiments, source/drain contacts 266 are formed extending through the ILD layer 264 and the ESL 262, the ILD layer 240, and the CESL 242 to the epitaxial source/drain regions 238A, 238B. The source/drain contacts 266 can be formed by, for example, etching contact openings extending through the ILD layer 264 and the ESL 262, the ILD layer 240, and the CESL 242 to the epitaxial source/drain regions 238A, 238B, depositing one or more metal materials into the contact openings, followed by removing excessive metal materials by using CMP. In some embodiments, silicide layers 260A, 260B are formed at portions of the epitaxial source/drain regions 238A, 238B exposed at bottoms of the contact openings. The silicide layers 260A, 260B can be formed by depositing a metal, such as Ni, Co or Ti, on the exposed portions of the epitaxial source/drain regions 238A, 238B, performing an annealing process that causes the metal to selectively react with the exposed portions of the epitaxial source/drain regions 238A, 238B, followed by removing unreacted portions of the metal, leaving the metal silicide layers 260A, 260B, respectively on the epitaxial source/drain regions 238A and 238B. In some embodiments, the electrical conductivity of the silicide layers 260A, 260B is greater than the electrical conductivity of the epitaxial source/drain regions 238A, 238B. In some embodiments, the source/drain contacts 266 have an electrical conductivity greater than the silicide layers 260A, 260B.

Gate contacts 268 are formed extending through the ILD layer 264 and the ESL 262 to the gate structures 250. The gate contacts 268 can be formed by, for example, etching contact openings extending through the ILD layer 264 and the ESL 262 to the gate structures 250, depositing one or more metal materials into the contact openings, followed by removing excessive metal materials by using CMP.

An ESL 272 is formed over the ILD layer 264, and an ILD layer 274 is formed over the ESL 272. In some embodiments, metal vias 276 are formed extending through the ILD layer 274 and the ESL 272 to electrically connect the source/drain contacts 266 and the gate contacts 268. An ESL 282 is formed over the ILD layer 274, and an ILD layer 284 is formed over the ESL 282. Metal lines 286 are formed in in the ILD layer 284 and the ESL 282 to electrically connect the vias 276.

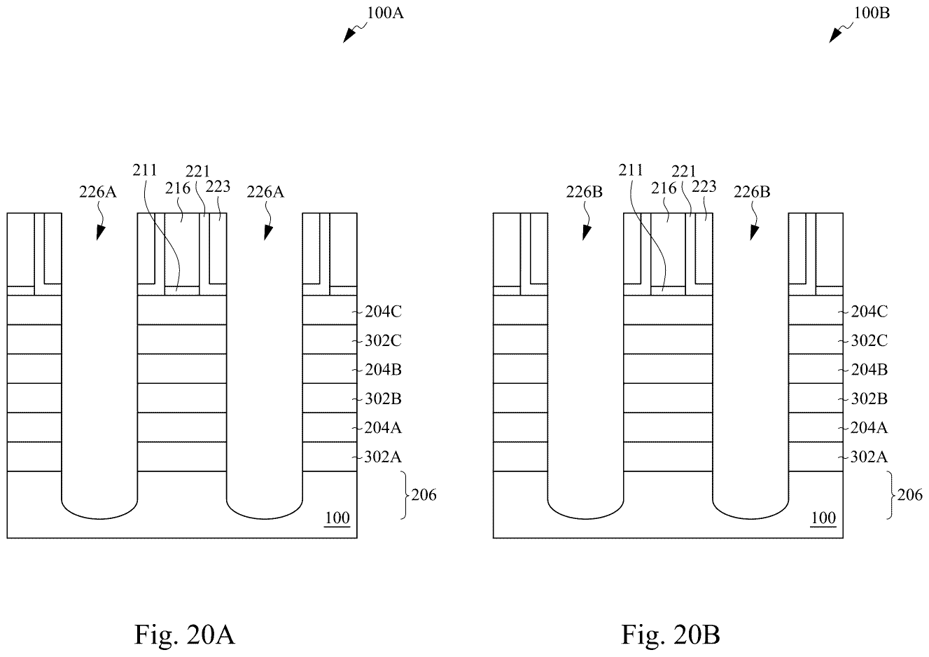

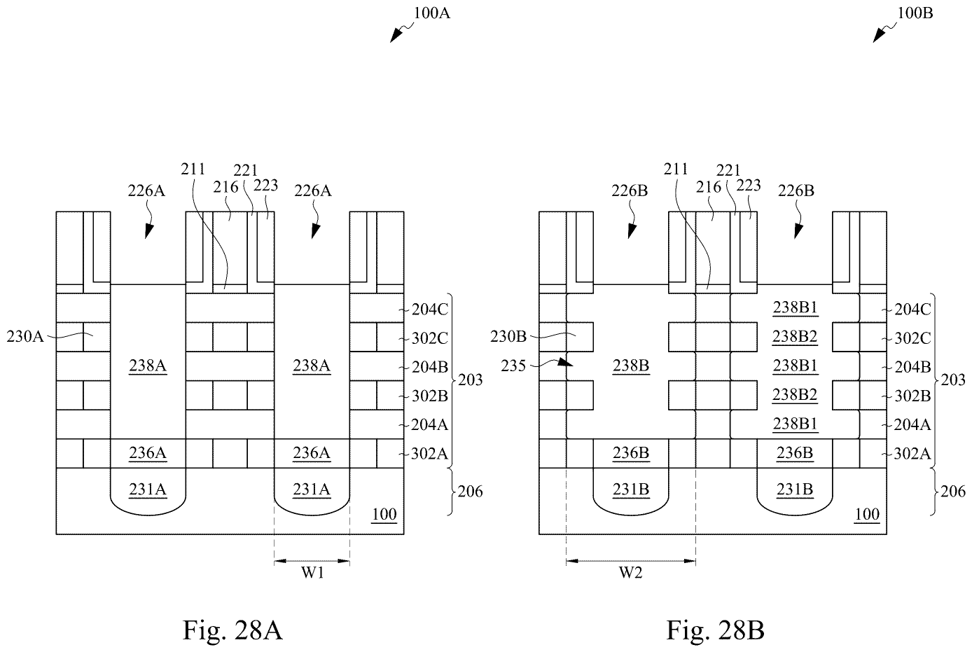

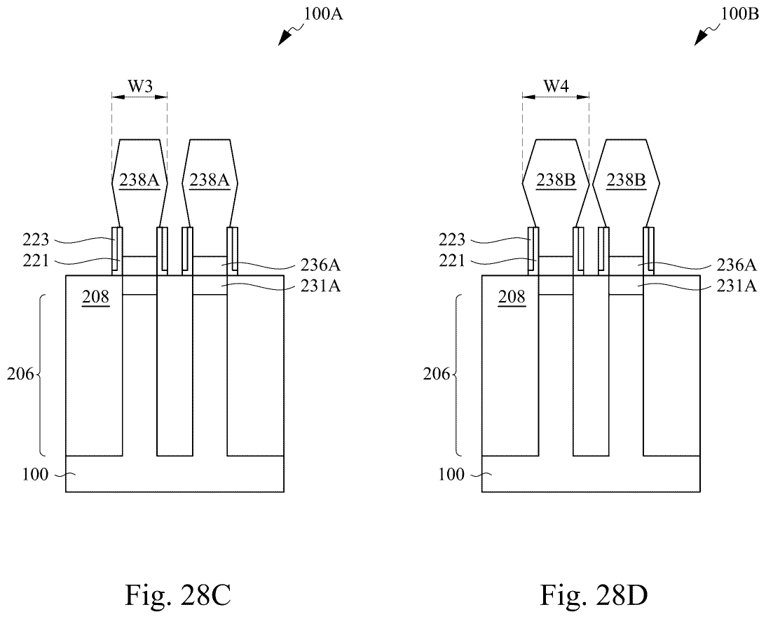

FIGS. 20A through 32B are cross-sectional views of intermediate stages in the manufacturing of GAA-FETs, in accordance with some embodiment. FIGS. 20A, 20B, 21A, 21B, 22A, 22B, 23A, 23B, 24A, 24B, 25A, 25B, 26A, 26B, 27A, 27B, 28A, 28B, 29A, 29B, 30A, 30B, 31A, 31B, 32A, 32B illustrate reference cross-section B-B′ illustrated in FIG. 1 that extends through a fin along a longitudinal axis of the fin. FIGS. 28C and 28D illustrate reference cross-section C-C′ illustrated in FIG. 1 that extends through source/drain regions along the longitudinal direction of the gate region.

FIGS. 20A and 20B illustrates a processing stage subsequent to FIGS. 7A and 7B. In the depicted embodiment, after source/drain recesses 226A and 226B are formed in the device regions 100A and 100B, the first nanostructures 202A-C are replaced with dielectric nanostructures 302A-C (collectively referred to as dielectric nanostructures 302). In some embodiments, the replacement includes selectively removing the first nanostructures 202 to form openings between corresponding second nanostructures 204, depositing a dielectric material (e.g., silicon oxide) filling the openings, followed by removing excessive portions of the dielectric material outside the openings by using suitable etching techniques.

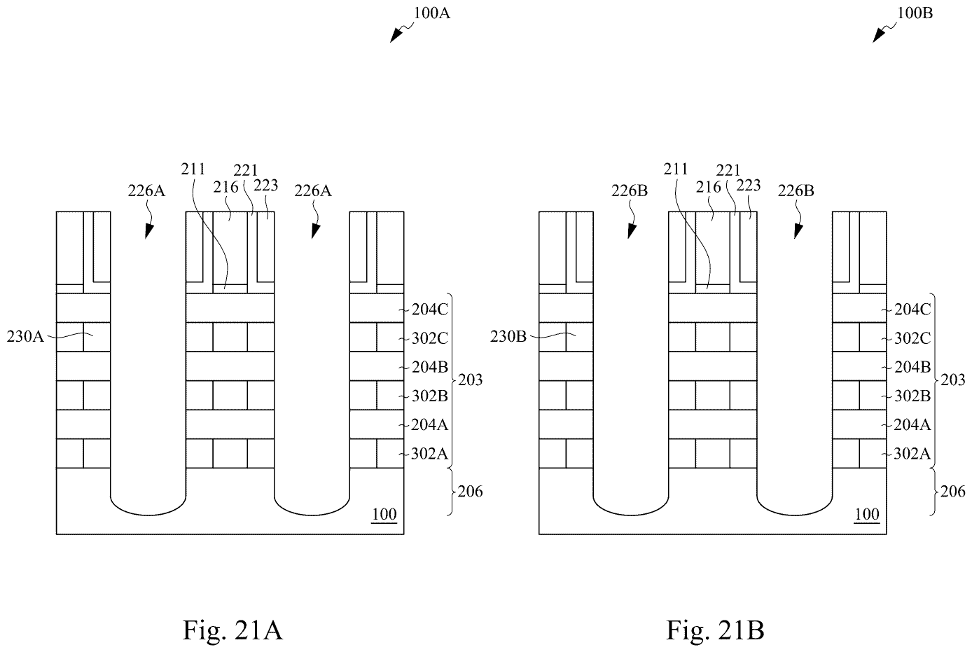

Next, in FIGS. 21A and 21B, sidewalls of the dielectric nanostructures 302 exposed by the source/drain recesses 226A, 226B are etched to form sidewall recesses between corresponding second nanostructures 204, followed by forming inner spacers 230A, 230B in the sidewall recesses in the dielectric nanostructures 302. Other details regarding the inner spacers 230A and 230B have been previously discussed in relation to FIGS. 8A and 8B, and are therefore not reiterated here for brevity.

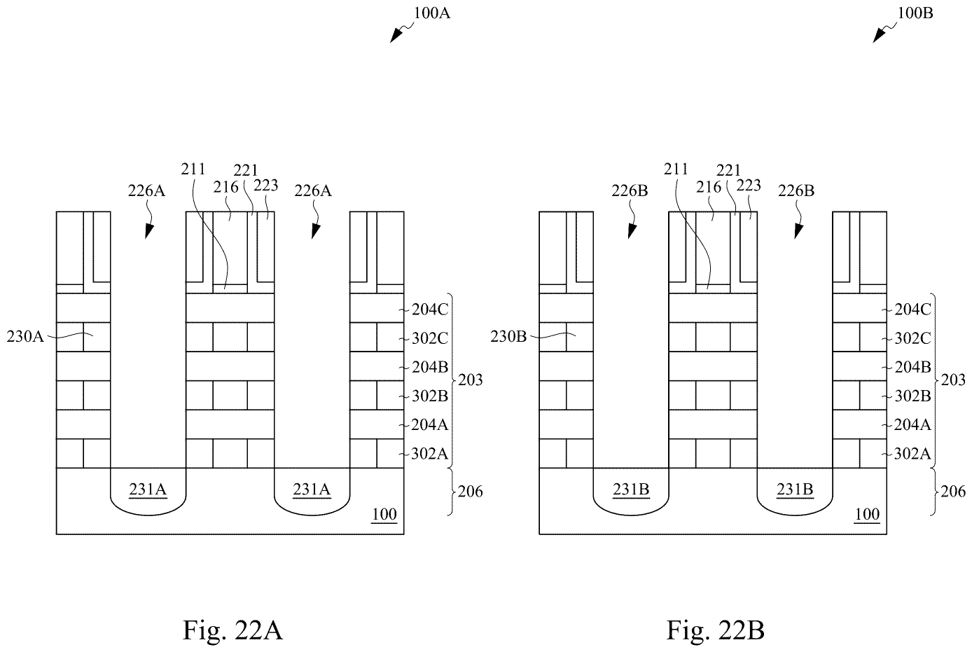

Next, in FIGS. 22A and 22B, first epitaxial layers 231A are formed in bottom portions of the source/drain recesses 226A within the first device region 100A, and first epitaxial layers 231B are formed in bottom portions of the source/drain recesses 226B within the first device region 100A. The first epitaxial layers 231A and 231B can include intrinsic silicon without a dopant. Other details regarding the first epitaxial layers 231A and 231B have been previously discussed in relation to FIGS. 9A and 9B, and are therefore not reiterated here for brevity.

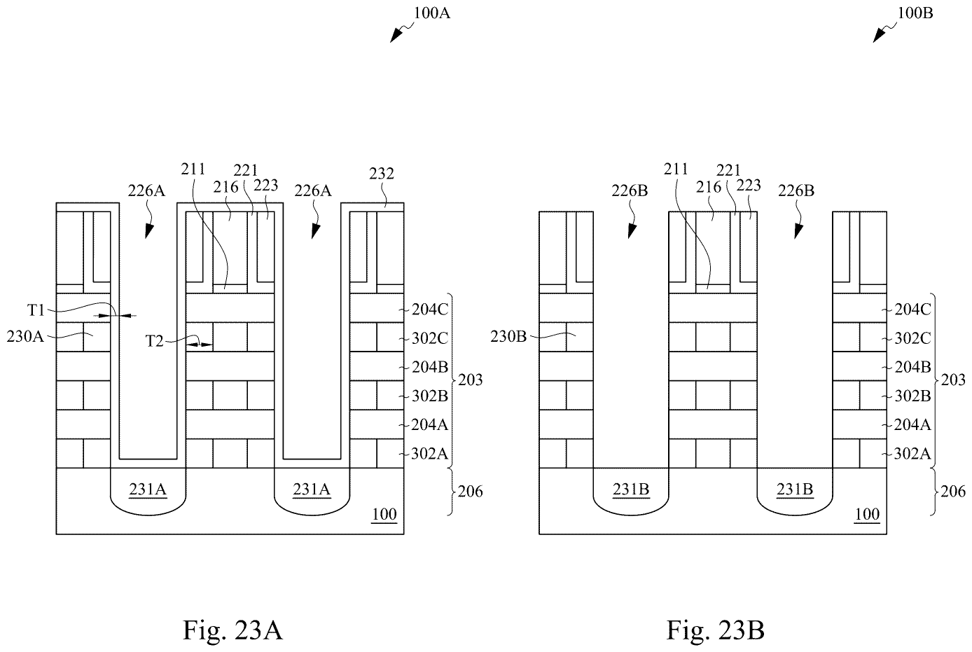

Next, in FIGS. 23A and 23B, a protective layer 232 is formed over the device region 100A, but not over the device region 100B. In some embodiments, the protective layer 232 can be formed by, for example, depositing a blanket layer of protective material globally over the substrate 100 by using ALD or CVD, followed by patterning the blanket layer of protective material into the protective layer 232 by using suitable lithography and etching techniques. Other details regarding the protective layer 232 have been previously discussed in relation to FIGS. 10A and 10B, and are therefore not reiterated here for brevity.

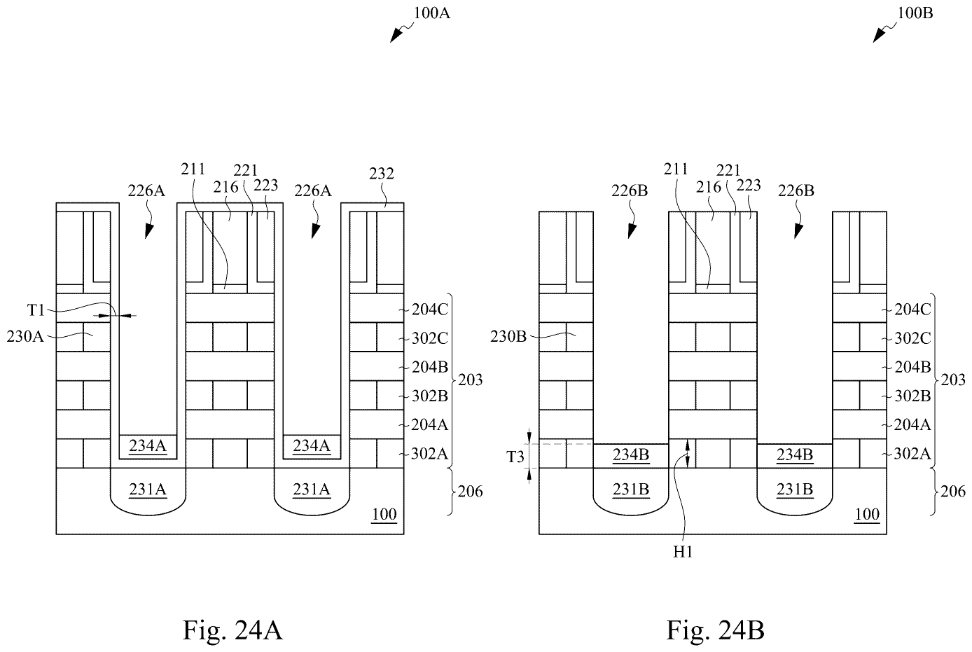

Next, in FIGS. 24A and 24B, protective structures 234A and 234B are formed in the source/drain recesses 226A within the device region 100A and in the source/drain recesses 226B within the device region 100B, respectively. Other details regarding the protective structures 234A and 234B have been previously discussed in relation to FIGS. 11A and 11B, and are therefore not reiterated here for brevity.

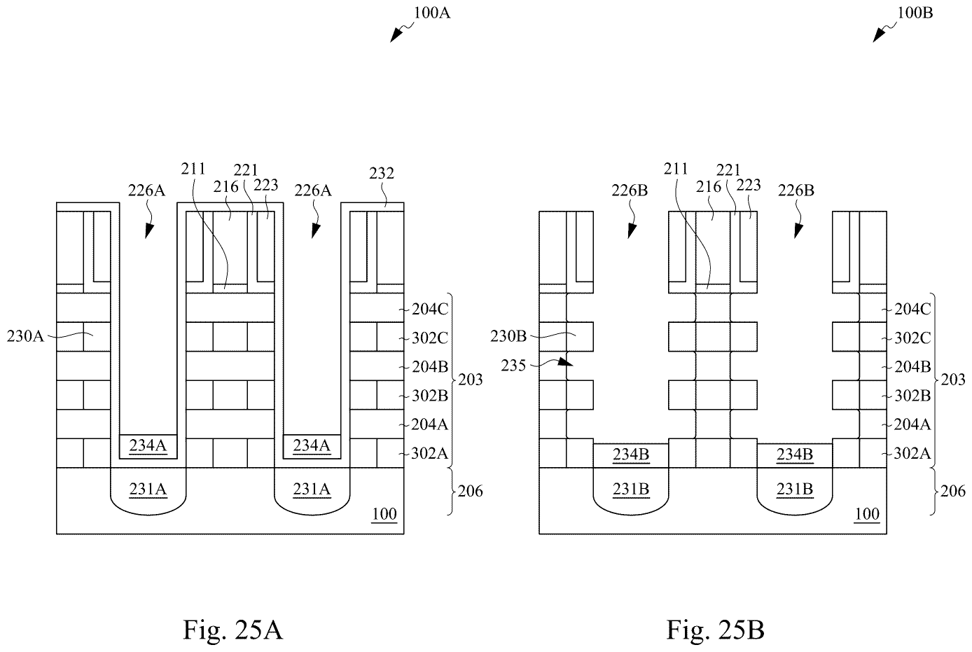

Next, in FIGS. 25A and 25B, a selective etching process is performed to selectively etch the second nanostructures 204 exposed in the source/drain recesses 226B within the device region 100B, while cause no or negligible etching amount in the protective structures 234A, 234B and in the protective layer 232. The selective etching process laterally etches the second nanostructures 204 exposed in the source/drain recesses 226B within the device region 100B, which in turn laterally expands the source/drain recesses 226B to have a larger lateral size. On the other hand, the source/drain recesses 226A within the device region 100A are not expanded by this selective etching process, because all sidewalls of the second nanostructures 204 within the source/drain recesses 226A are covered and protected by the protective layer 232. Other details regarding the selective etching step have been previously discussed in relation to FIGS. 12A and 12B, and are therefore not reiterated here for brevity.

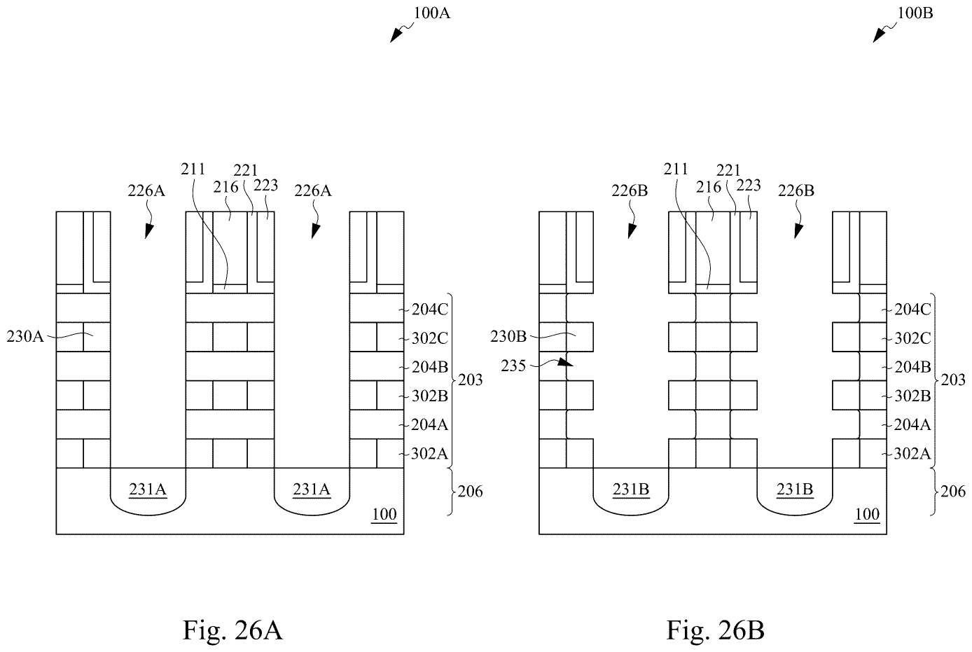

Next, in FIGS. 26A and 26B, the protective structures 234A, 234B, and the protective layer 232 are removed, for example, in a single wet etching process. Other details regarding the removal step have been previously discussed in relation to FIGS. 13A and 13B, and are therefore not reiterated here for brevity.

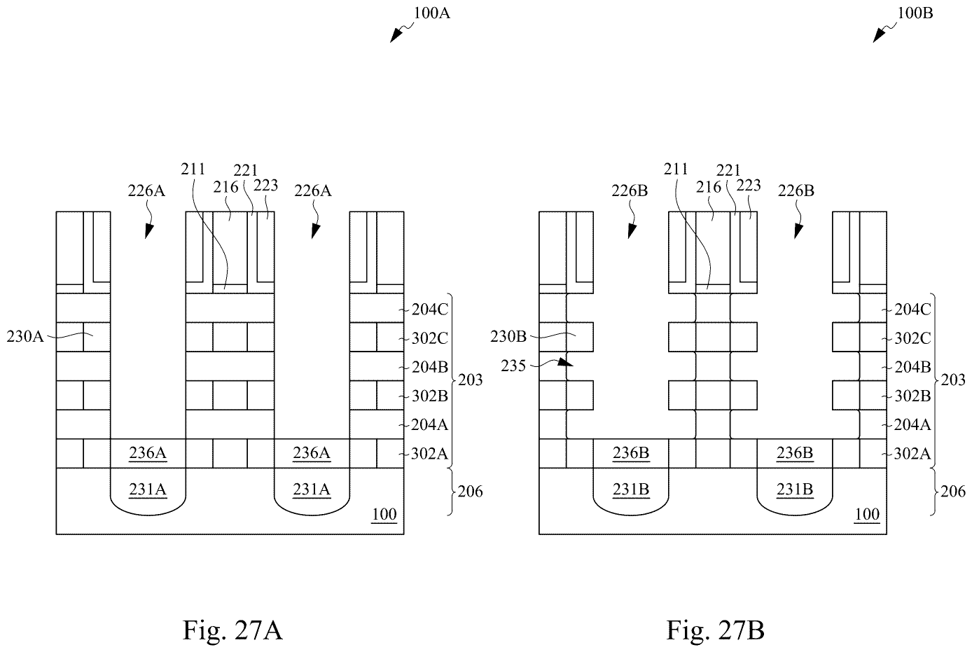

Next, in FIGS. 27A and 27B, bottom isolation structures 236A and 236B are formed in bottom portions of the source/drain recesses 226A within the device region 100A and in the source/drain recesses 226B within the device region 100B, respectively. Other details regarding the removal step have been previously discussed in relation to FIGS. 14A and 14B, and are therefore not reiterated here for brevity.

Next, in FIGS. 28A-28D, epitaxial source/drain regions (also referred to as epitaxial features or epitaxial source/drain features) 238A, 238B are formed in the source/drain recesses 226A, 226B, respectively. In some embodiments, the epitaxial source/drain region 238B has a plurality of first epitaxial portions 238B1 and a plurality of second epitaxial portions 238B2 alternating with the first epitaxial portions 238B1, and the second epitaxial portions 238B2 has a width less than a width of the first epitaxial portions 238B1. The first epitaxial portions 238B1 have opposite sidewalls interfacing the second nanostructures 204, and the second epitaxial portions 238B2 have opposite sidewalls interfacing the inner spacers 230B. Other details regarding the epitaxial source/drain regions 238A, 238B have been previously discussed in relation to FIGS. 15A and 15B, and are therefore not reiterated here for brevity.

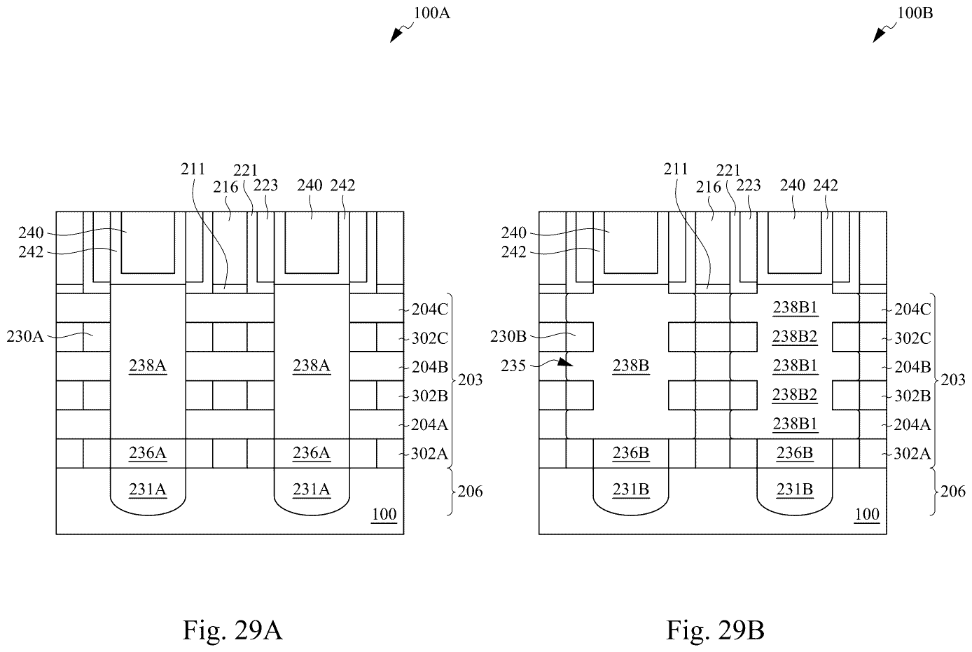

Next, in FIGS. 29A-29B, CESL 242 and an ILD layer 240 are formed over the structure as illustrated in FIGS. 28A-28D. Other details regarding the CESL 242 and the ILD layer 240 have been previously discussed in relation to FIGS. 16A and 16B, and are therefore not reiterated here for brevity.

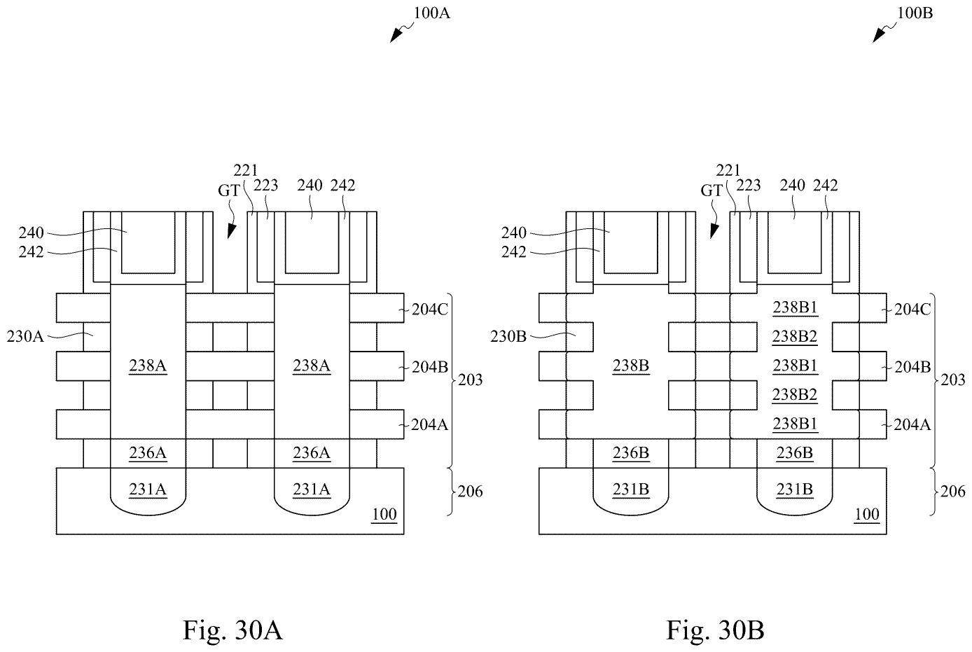

Next, in FIGS. 30A and 30B, the dummy gates 216 are removed to form gate trenches GT are formed between corresponding gate spacers 221, followed by removing the dielectric nanostructures 302 by using a selective etching process using etchants which are selective to the dielectric material of the dielectric nanostructures 302. Stated differently, the dielectric nanostructures 302 are removed by using a selective etching process that etches the dielectric nanostructures 302 at a faster etch rate than it etches the second nanostructures 204, thus forming spaces between the second nanostructures 204 (also referred to as sheet-to-sheet spaces if the nanostructures 204 are nanosheets). In embodiments in which the dielectric nanostructures 302 include, e.g., silicon oxide, and the second nanostructures 204 include, e.g., Si or SiC, hydrofluoric acid (HF) or the like may be used to remove the dielectric nanostructures 302.

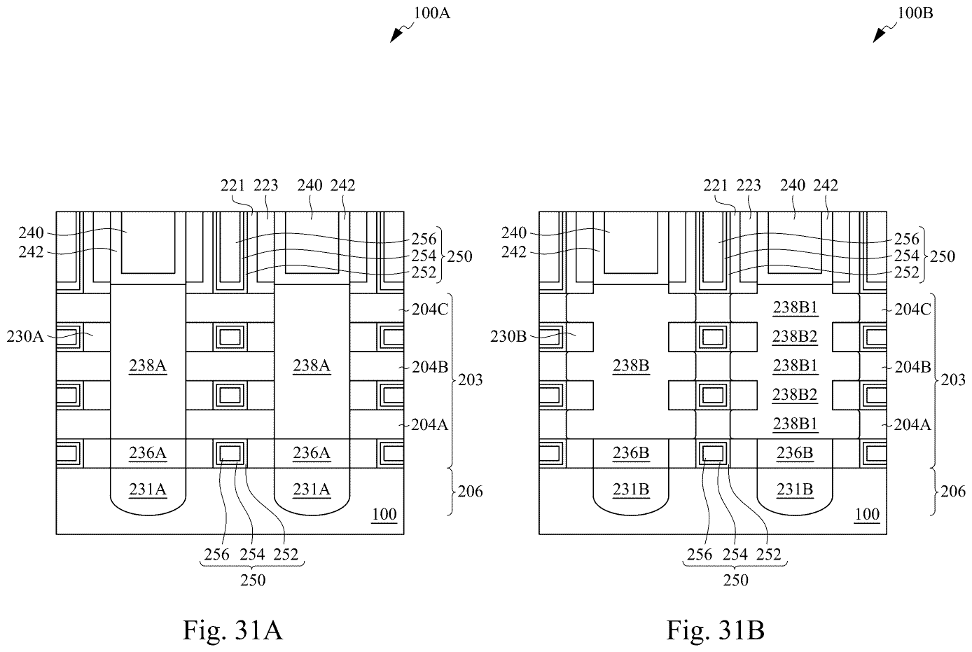

Next, in FIGS. 31A-31B, replacement gate structures 250 are respectively formed in the gate trenches GT to surround each of the nanostructures 204 suspended in the gate trenches GT. In some embodiments, the replacement gate structure 250 is a high-k/metal gate structure, which includes a gate dielectric layer 252 formed around the nanostructures 204, a work function metal layer 254 formed around the gate dielectric layer 252, and a fill metal layer 256 formed around the work function metal layer 254 and filling a remainder of gate trenches GT. Other details regarding the gate structures 250 have been previously discussed in relation to FIGS. 18A-18D, and are therefore not reiterated here for brevity.

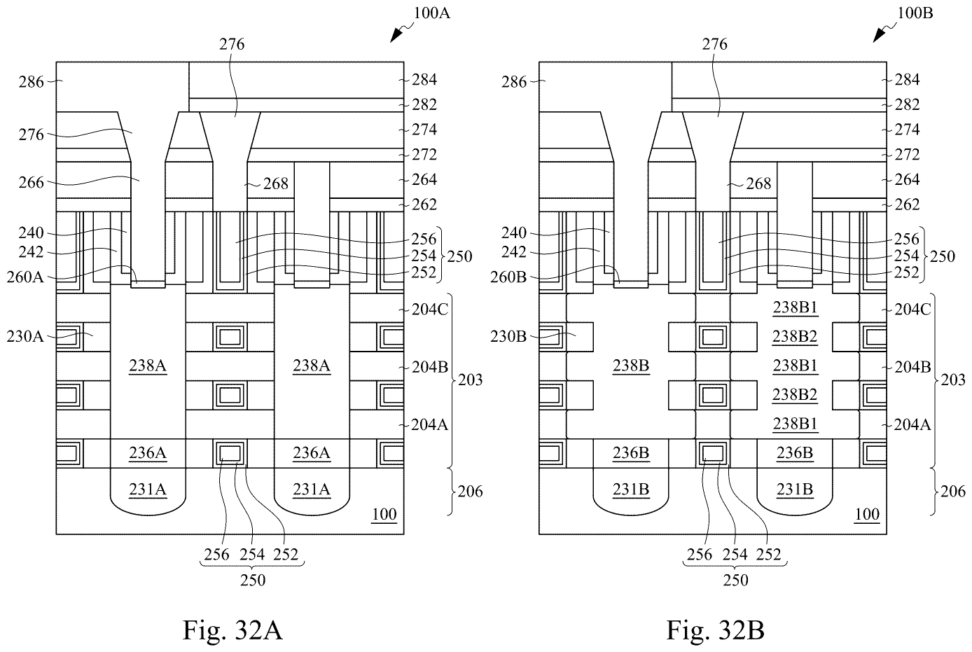

Next, in FIGS. 32A-32B, contact metals and their surrounding dielectrics are formed in middle-end-of-line (MEOL) processing. In some embodiments, an ESL 262 and an ILD layer 264 are formed over the gate structures 250. Source/drain contacts 266 are formed extending through the ILD layer 264, the ESL 262, the ILD layer 240, and the CESL 242 to electrically connect with the epitaxial source/drain regions 238A, 238B. Gate contacts 268 are formed extending through the ILD layer 264 and the ESL 262 to electrically connect with the gate structures 250. In some embodiments, silicide layers 260A are formed between the epitaxial source/drain regions 238A and the source/drain contacts 266, silicide layers 260B are formed between the epitaxial source/drain regions 238B and the source/drain contacts 266. An ESL 272 is formed over the ILD layer 264, and an ILD layer 274 is formed over the ESL 272. Metal vias 276 are formed in the ILD layer 274 and the ESL 272 to electrically connect with the source/drain contacts 266 and gate contacts 268, respectively. An ESL 272 and an ILD layer 284 are formed over the ILD layer 274. Metal lines 286 are formed in the ILD layer 284 and the ESL 272 to electrically connect with the underlying vias 276. Other details regarding the silicide layers, metal contacts, metal vias, and metal lines have been previously discussed in relation to FIGS. 19A-19B, and are therefore not reiterated here for brevity.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that protective structures prevent the un-doped epitaxial regions from being unintentionally etched during the lateral etching process. By maintaining uniformity in the height of the un-doped epitaxial regions between high-current-demand and lower-current-demand transistors, the risk of leakage currents can be reduced when isolation layers are deposited over these regions.

In some embodiments, a method includes following steps: forming a first gate structure (e.g., dummy gate 216) over a first active region (e.g., active region 205), and a second gate structure (e.g., another dummy gate 216) over a second active region (e.g., another active region 205); etching a first source/drain recess (e.g., recess 226A) in the first active region, and a second source/drain recess (e.g., recess 226B) in the second active region; forming a first epitaxial layer (e.g., layer 231A) in a bottom portion of the first source/drain recess, and a second epitaxial layer (e.g., layer 231B) in a bottom portion of the first source/drain recess; forming a protective layer (e.g., layer 232) lining the first source/drain recess; forming a first protective structure (e.g., structure 234A) over the protective layer, and a second protective structure (e.g., structure 234B) over the second epitaxial layer; with the first and second protective structures in place, laterally expanding the second source/drain recess; and forming a first epitaxial structure (e.g., structure 238A) in the first source/drain recess, and a second epitaxial structure (e.g., structure 238B) in the second source/drain recess. In some embodiments, the first protective structure comprises amorphous carbon, and the second protective structure comprises amorphous carbon. In some embodiments, the protective layer comprises metal oxide. In some embodiments, after forming the first and second protective structures, the second epitaxial layer has a greater carbon atomic concentration than the first epitaxial layer. In some embodiments, the method further includes prior to forming the first epitaxial structure and the second epitaxial structure, removing the protective layer, the first protective structure, and the second protective structure. In some embodiments, the method further includes after removing the protective layer, the first protective structure, and the second protective structure, forming a first isolation structure (e.g., structure 236A) over the first epitaxial layer, and a second isolation structure (e.g., structure 236B) over the second epitaxial layer. In some embodiments, the first isolation structure has a top surface substantially level with a top surface of the second isolation structure. In some embodiments, the first epitaxial structure is formed on the first isolation structure, and the second epitaxial structure is formed on the second isolation structure. In some embodiments, the second epitaxial structure comprises a plurality of first epitaxial portions and a plurality of second epitaxial portions alternating with the plurality of first epitaxial portions. One of the first epitaxial portions has a width greater than one of the second epitaxial portions.

In some embodiments, a method includes following steps: forming a first channel region (e.g., 204 in device region 100A) and a second channel region (e.g., 204 in device region 100B) over a substrate; forming a first gate structure (e.g., 250 in device region 100A) over the first channel region, and a second gate structure (e.g., 250 in device region 100B) over the second channel region; forming a first epitaxial layer (e.g., 231A) and a second epitaxial layer (e.g., 231B) in the substrate, wherein the second epitaxial layer has a greater carbon atomic concentration than the first epitaxial layer; forming a first epitaxial structure (e.g., 238A) interfacing a sidewall of the first channel region and disposed over the first epitaxial layer, and a second epitaxial structure (e.g., 238B) interfacing a sidewall of the second channel region and disposed over the second epitaxial layer. The second epitaxial structure has a maximal width greater than a maximal width of the first epitaxial structure. In some embodiments, the method further includes forming a first isolation structure (e.g., 236A) disposed between the first epitaxial layer and the first epitaxial structure, and forming a second isolation structure (e.g., 236B) disposed between the second epitaxial layer and the second epitaxial structure. In some embodiments, the method further includes forming first inner spacers (e.g., 230A) disposed at opposite sides of the first isolation structure, and forming second inner spacers (e.g., 230B) disposed at opposite sides of the second isolation structure. One of the second inner spacers has a greater carbon atomic concentration than one of the first inner spacers. In some embodiments, the method further comprises prior to forming the first epitaxial structure and the second epitaxial structure, forming a first protective structure (e.g., 234A) over the first epitaxial layer, and a second protective structure (e.g., 234B) over the second epitaxial layer, wherein the second protective structure is in contact with the second epitaxial layer, and the first protective structure is spaced apart from the first epitaxial layer. In some embodiments, the first protective structure and the second protective structure are carbon-containing structures. In some embodiments, the method further comprises prior to forming the first epitaxial structure and the second epitaxial structure, removing the first protective structure and the second protective structure.

In some embodiments, a device includes a first active region (e.g., 205 in device region 100A) and a second active region (e.g., 205 in device region 100B) disposed over a substrate and extending lengthwise along a first direction; a first isolation feature (e.g., 208 in device region 100A) disposed over the substrate and alongside the first active region; a second isolation feature (e.g., 208 in device region 100B) disposed over the substrate and alongside the second active region; a first source/drain feature (e.g., 238A) disposed over the first active region, wherein a portion of the first source/drain feature overhangs the first isolation feature; a second source/drain feature (e.g., 238B) disposed over the second active region, wherein a portion of the second source/drain feature overhangs the second isolation feature; an interlayer dielectric (ILD) layer (e.g., 240) disposed over the first source/drain feature and the second source/drain feature; a first source/drain contact (e.g., 266 in device region 100A) and a second source/drain contact (e.g., 266 in device region 100B) disposed in the ILD layer to electrically couple to the first source/drain feature and the second source/drain feature, respectively; a first epitaxial layer (e.g., 231A) embedded in the substrate and overlapping with the first source/drain feature; and a second epitaxial layer (e.g., 231B) embedded in the substrate and overlapping with the second source/drain feature, wherein the second epitaxial layer has a greater carbon atomic concentration than the first epitaxial layer. In some embodiments, the device further includes a first isolation structure (e.g., 236A) disposed between the first source/drain feature and the first epitaxial layer; and a second isolation structure (e.g., 236B) disposed between the second source/drain feature and the second epitaxial layer. In some embodiments, the first isolation structure has a top surface substantially level with a top surface of the second isolation structure. In some embodiments, the device further includes first inner spacers (e.g., 230A) at opposite sides of the first isolation structure; and second inner spacers (e.g., 230B) at opposite sides of the second isolation structure. One of the second inner spacers has a greater carbon atomic concentration than one of the first inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first gate structure over a first active region, and a second gate structure over a second active region;
etching a first source/drain recess in the first active region, and a second source/drain recess in the second active region;
forming a first epitaxial layer in a bottom portion of the first source/drain recess, and a second epitaxial layer in a bottom portion of the first source/drain recess;
forming a protective layer lining the first source/drain recess;
forming a first protective structure over the protective layer, and a second protective structure over the second epitaxial layer;
with the first and second protective structures in place, laterally expanding the second source/drain recess; and
forming a first epitaxial structure in the first source/drain recess, and a second epitaxial structure in the second source/drain recess.

2. The method of claim 1, wherein the first protective structure comprises amorphous carbon.

3. The method of claim 1, wherein the second protective structure comprises amorphous carbon.

4. The method of claim 1, wherein the protective layer comprises metal oxide.

5. The method of claim 1, wherein after forming the first and second protective structures, the second epitaxial layer has a greater carbon atomic concentration than the first epitaxial layer.

6. The method of claim 1, further comprising:
prior to forming the first epitaxial structure and the second epitaxial structure, removing the protective layer, the first protective structure, and the second protective structure.

7. The method of claim 6, further comprising:
after removing the protective layer, the first protective structure, and the second protective structure, forming a first isolation structure over the first epitaxial layer, and a second isolation structure over the second epitaxial layer.

8. The method of claim 7, wherein the first isolation structure has a top surface substantially level with a top surface of the second isolation structure.

9. The method of claim 7, wherein the first epitaxial structure is formed on the first isolation structure, and the second epitaxial structure is formed on the second isolation structure.

10. The method of claim 1, wherein the second epitaxial structure comprises a plurality of first epitaxial portions and a plurality of second epitaxial portions alternating with the plurality of first epitaxial portions, wherein one of the first epitaxial portions has a width greater than one of the second epitaxial portions.

11. A method comprising:
forming a first channel region and a second channel region over a substrate;
forming a first gate structure over the first channel region, and a second gate structure over the second channel region;
forming a first epitaxial layer and a second epitaxial layer in the substrate, wherein the second epitaxial layer has a greater carbon atomic concentration than the first epitaxial layer; and
forming a first epitaxial structure interfacing a sidewall of the first channel region and disposed over the first epitaxial layer, and a second epitaxial structure interfacing a sidewall of the second channel region and disposed over the second epitaxial layer, the second epitaxial structure having a maximal width greater than a maximal width of the first epitaxial structure.

12. The method of claim 11, further comprising:
forming a first isolation structure disposed between the first epitaxial layer and the first epitaxial structure; and
forming a second isolation structure disposed between the second epitaxial layer and the second epitaxial structure.

13. The method of claim 12, further comprising:
forming first inner spacers disposed at opposite sides of the first isolation structure; and
forming second inner spacers disposed at opposite sides of the second isolation structure, wherein one of the second inner spacers has a greater carbon atomic concentration than one of the first inner spacers.

14. The method of claim 11, further comprising:
prior to forming the first epitaxial structure and the second epitaxial structure, forming a first protective structure over the first epitaxial layer, and a second protective structure over the second epitaxial layer, wherein the second protective structure is in contact with the second epitaxial layer, and the first protective structure is spaced apart from the first epitaxial layer.

15. The method of claim 14, wherein the first protective structure and the second protective structure are carbon-containing structures.

16. The method of claim 14, further comprising:
prior to forming the first epitaxial structure and the second epitaxial structure, removing the first protective structure and the second protective structure.

17. A device comprising:
a first active region and a second active region disposed over a substrate and extending lengthwise along a first direction;
a first isolation feature disposed over the substrate and alongside the first active region;
a second isolation feature disposed over the substrate and alongside the second active region;
a first source/drain feature disposed over the first active region, wherein a portion of the first source/drain feature overhangs the first isolation feature;
a second source/drain feature disposed over the second active region, wherein a portion of the second source/drain feature overhangs the second isolation feature;
an interlayer dielectric (ILD) layer disposed over the first source/drain feature and the second source/drain feature;
a first source/drain contact and a second source/drain contact disposed in the ILD layer to electrically couple to the first source/drain feature and the second source/drain feature, respectively;
a first epitaxial layer embedded in the substrate and overlapping with the first source/drain feature; and
a second epitaxial layer embedded in the substrate and overlapping with the second source/drain feature, wherein the second epitaxial layer has a greater carbon atomic concentration than the first epitaxial layer.

18. The device of claim 17, further comprising:
a first isolation structure disposed between the first source/drain feature and the first epitaxial layer; and
a second isolation structure disposed between the second source/drain feature and the second epitaxial layer.

19. The device of claim 18, wherein the first isolation structure has a top surface substantially level with a top surface of the second isolation structure.

20. The device of claim 18, further comprising:
first inner spacers at opposite sides of the first isolation structure; and
second inner spacers at opposite sides of the second isolation structure, wherein one of the second inner spacers has a greater carbon atomic concentration than one of the first inner spacers.
